(19) United States
(12) Patent Application Publication
(10) Pub. No.: US 2003/0017722 A1
(43) Pub. Date: Jan. 23, 2003

(54) Structure and method for fabricating an integrated phased array circuit

(75) Inventor: Rudy M. Emrick, Gilbert, AZ (US)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MOTOROLA, INC, Schaumburg, IL

(21) Appl. No.: 09/905,933

(22) Filed: Jul. 17, 2001

(51) Int. Cl. H01L 21/00; C30B 1/00; H01L 21/20; H01L 21/36; H01L 21/31; H01L 29/76

(52) U.S. Cl. 438/800; 438/496; 438/763; 257/370; 257/350

(57) ABSTRACT

Phased array components utilizing two or more different types of semiconductor in one monolithic device are provided. High quality epitaxil layers of monocrystalline materials can be grown overlying monocrystalline substrates such as large silicon wafers by forming a compliant substrate for growing the monocrystalline layers. An accommodating buffer layer comprises a layer of monocrystalline oxide spaced apart from a silicon wafer by an amorphous interface layer of silicon oxide. The amorphous interface layer dissipates strain and permits the growth of a high quality monocrystalline oxide accommodating buffer layer. The accommodating buffer layer is lattice matched to both the underlying silicon wafer and the overlying monocrystalline material layer. Any lattice mismatch between the accommodating buffer layer and the underlying silicon substrate is taken care of by the amorphous interface layer. In addition, formation of a compliant substrate may include utilizing surfactant enhanced epitaxy, epitaxil growth of single crystal silicon onto single crystal oxide, and epitaxil growth of Zintl phase materials.

### FIELD OF THE INVENTION

This invention relates generally to semiconductor structures and devices and to a method for their fabrication, and more specifically to semiconductor structures and devices and to the fabrication and use of semiconductor structures, devices, and integrated circuits that include a monocrystalline material layer comprised of semiconductor material, compound semiconductor material, and/or other types of material such as metals and non-metals.

### BACKGROUND OF THE INVENTION

Phased array circuits include separate application specific integrated circuits, phase shifters, low noise amplifiers, power amplifiers and/or other components. These components have been typically connected together by wires or traces that may be lossy. Separate components have been used due to the constraints of the semiconductor materials on which the components are formed that have minimized the practicality of more fully integrated devices.

Semiconductor devices often include multiple layers of conductive, insulating, and semiconductive layers. Often, the desirable properties of such layers improve with the crystallinity of the layer. For example, the electron mobility and band gap of semiconductive layers improves as the crystallinity of the layer increases. Similarly, the free electron concentration of conductive layers and the electron charge displacement and electron energy recoverability of insulative or dielectric films improves as the crystallinity of these layers increases.

For many years, attempts have been made to grow various monolithic thin films on a foreign substrate such as silicon (Si). To achieve optimal characteristics of the various monolithic layers, however, a monocrystalline film of high crystalline quality is desired. Attempts have been made, for example, to grow various monocrystalline layers on a substrate such as germanium, silicon, and various insulators. These attempts have generally been unsuccessful because lattice mismatches between the host crystal and the grown crystal have caused the resulting layer of monocrystalline material to be of low crystalline quality.

If a large area thin film of high quality monocrystalline material was available at low cost, a variety of semiconductor devices could advantageously be fabricated in or using that film at a low cost compared to the cost of fabricating such devices beginning with a bulk wafer of semiconductor material or in an epitaxial film of such material on a bulk wafer of semiconductor material. In addition, if a thin film of high quality monocrystalline material could be realized beginning with a bulk wafer such as a silicon wafer, an integrated device structure could be achieved that took advantage of the best properties of both the silicon and the high quality monocrystalline material.

Accordingly, a need exists for a semiconductor structure that provides a high quality monocrystalline film or layer over another monocrystalline material and for a process for making such a structure. In other words, there is a need for providing the formation of a monocrystalline substrate that is compliant with a high quality monocrystalline material layer so that true two-dimensional growth can be achieved for the formation of quality semiconductor structures, devices and integrated circuits having grown monocrystalline film having the same crystal orientation as an underlying substrate. This monocrystalline material layer may be comprised of a semiconductor material, a compound semiconductor material, and other types of material such as metals and non-metals.

### BRIEF DESCRIPTION OF THE DRAWINGS

The present invention is illustrated by way of example and not limitation in the accompanying figures, in which like references indicate similar elements, and in which:

FIGS. 1, 2, and 3 illustrate schematically, in cross section, device structures in accordance with various embodiments of the invention;

FIG. 4 illustrates graphically the relationship between maximum attainable film thickness and lattice mismatch between a host crystal and a grown crystalline overlayer;

FIG. 5 illustrates a high resolution Transmission Electron Micrograph of a structure including a monocrystalline accommodating buffer layer;

FIG. 6 illustrates an x-ray diffraction spectrum of a structure including a monocrystalline accommodating buffer layer;

FIG. 7 illustrates a high resolution Transmission Electron Micrograph of a structure including an amorphous oxide layer;

FIG. 8 illustrates an x-ray diffraction spectrum of a structure including an amorphous oxide layer;

FIGS. 9-12 illustrate schematically, in cross-section, the formation of a device structure in accordance with another embodiment of the invention;

FIGS. 13-16 illustrate a probable molecular bonding structure of the device structures illustrated in FIGS. 9-12;

FIGS. 17-20 illustrate schematically, in cross-section, the formation of a device structure in accordance with still another embodiment of the invention;

FIGS. 21-23 illustrate schematically, in cross-section, the formation of yet another embodiment of a device structure in accordance with the invention;

FIGS. 21-23 illustrate schematically, in cross section, the formation of a yet another embodiment of a device structure in accordance with the invention;

FIGS. 24, 25 illustrate schematically, in cross section, device structures that can be used in accordance with various embodiments of the invention;

FIGS. 26-30 include illustrations of cross-sectional views of a portion of an integrated circuit that includes a compound semiconductor portion, a bipolar portion, and an MOS portion in accordance with what is shown herein;

FIG. 31 includes an illustration of a cross-sectional view of a portion of another integrated circuit that includes a MOS transistor in accordance with what is shown herein;

FIG. 32 illustrates one embodiment of a phased array monolithic device;

FIGS. 33-34 illustrate circuit diagrams of transmit or receive paths of a phased array cell of FIG. 32;

FIGS. 35, 36 illustrate circuit diagrams of transceivers of a phased array cell of FIG. 32; and

FIG. 37 illustrates a circuit diagram of a receive path of a phased array cell of FIG. 32.

FIG. 38 is a flow chart showing steps of the process to fabricate the phased array monolithic device.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE DRAWINGS

Phased array circuits are integrated onto one monolithic device having two different monocrystalline semiconductor materials, such as a monocrystalline silicon substrate and a monocrystalline compound semiconductor material. Phased array components formed in one material, such as a Group IV material, are integrated with phased array components formed in another material, such as compound semiconductor materials. Using different materials, different phased array components may be integrated on one monolithic device, such as a low noise amplifier formed in a compound semiconductor material and a control transistor network formed in silicon. Phased arrays include a plurality of cells (i.e. transmit and/or receive circuits), so integration on one monolithic device allows for low cost, low loss implementation of phased array circuits. Different materials in one integrated circuit also provide for phased array components operable over a broader range of frequencies. In alternative embodiments, a plurality of phased array components are formed in compound semiconductor materials that are larger due to growth on a Group IV substrate.

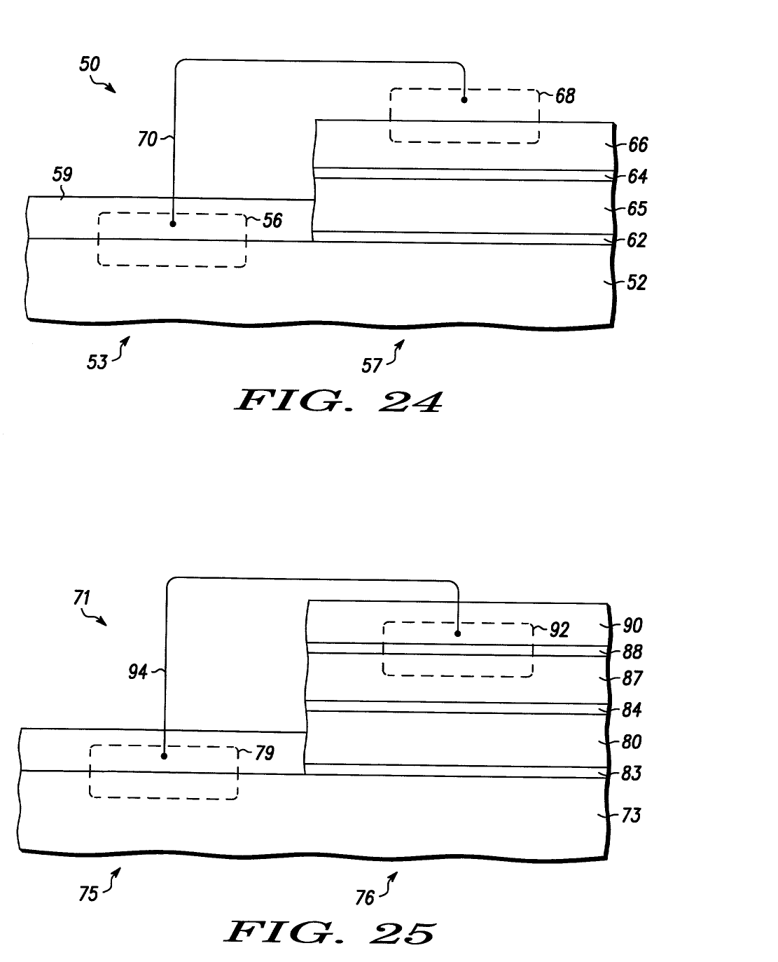

The phase array circuit is (1) formed on a monolithic device having a plurality of different semiconductor materials, (2) formed of semiconductor or other devices, and (3) comprises combinations of the semiconductor devices. The description related to FIGS. 1-23 describe formation of the monolithic device. The description related to FIGS. 24-31 describe formation of exemplary semiconductor devices. The description related to FIGS. 32-37 describe the combinations of the semiconductor and other devices to form phased array components.

FIG. 1 illustrates schematically, in cross section, a portion of a semiconductor structure 20 in accordance with an embodiment of the invention. Semiconductor structure 20 includes a monocrystalline substrate 22, accommodating buffer layer 24 comprising a monocrystalline material, and a monocrystalline material layer 26. In this context, the term “monocrystalline” shall have the meaning commonly used within the semiconductor industry. The term shall refer to materials that are a single crystal or that are substantially a single crystal and shall include those materials having a relatively small number of defects such as dislocations and the like as are commonly found in substrates of silicon or germanium or mixtures of silicon and germanium and epitaxial layers of such materials commonly found in the semiconductor industry.

In accordance with one embodiment of the invention, structure 20 also includes an amorphous intermediate layer 28 positioned between substrate 22 and accommodating buffer layer 24. Structure 20 may also include a template layer 30 between the accommodating buffer layer and monocrystalline material layer 26. As will be explained more fully below, the template layer helps to initiate the growth of the monocrystalline material layer on the accommodating buffer layer. The amorphous intermediate layer helps to relieve the strain in the accommodating buffer layer and by doing so, aids in the growth of a high crystalline quality accommodating buffer layer.

Substrate 22, in accordance with an embodiment of the invention, is a monocrystalline semiconductor or compound semiconductor wafer, preferably of large diameter. The wafer can be of, for example, a material from Group IV of the periodic table. Examples of Group IV semiconductor materials include silicon, germanium, mixed silicon and germanium, mixed silicon and carbon, mixed silicon, germanium and carbon, and the like. Preferably substrate 22 is a wafer containing silicon or germanium, and most preferably is a high quality monocrystalline silicon wafer as used in the semiconductor industry. Accommodating buffer layer 24 is preferably a monocrystalline oxide or nitride material epitaxially grown on the underlying substrate. In accordance with one embodiment of the invention, amorphous intermediate layer 28 is grown on substrate 22 at the interface between substrate 22 and the growing accommodating buffer layer by the oxidation of substrate 22 during the growth of layer 24. The amorphous intermediate layer serves to relieve strain that might otherwise occur in the monocrystalline accommodating buffer layer as a result of differences in the lattice constants of the substrate and the buffer layer. As used herein, lattice constant refers to the distance between atoms of a cell measured in the plane of the surface. If such strain is not relieved by the amorphous intermediate layer, the strain may cause defects in the crystalline structure of the accommodating buffer layer. Defects in the crystalline structure of the accommodating buffer layer, in turn, would make it difficult to achieve a high quality crystalline structure in monocrystalline material layer 26 which may comprise a semiconductor material, a compound semiconductor material, or another type of material such as a metal or a non-metal.

Accommodating buffer layer 24 is preferably a monocrystalline oxide or nitride material selected for its crystalline compatibility with the underlying substrate and with the overlying material layer. For example, the material could be an oxide or nitride having a lattice structure closely matched to the substrate and to the subsequently applied monocrystalline material layer. Materials that are suitable for the accommodating buffer layer include metal oxides such as the alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, alkaline earth metal tin-based perovskites, lanthanum aluminate, lanthanum scandium oxide, and gadolinium oxide. Additionally, various nitrides such as gallium nitride, aluminum nitride, and boron nitride may also be used for the accommodating buffer layer. Most of these materials are insulators, although strontium ruthenate, for example, is a conductor. Generally, these materials are metal oxides or metal nitrides, and more particularly, these metal oxide or nitrides typically include at least two different metallic elements. In some specific applications, the metal oxides or nitrides may include three or more different metallic elements.

Amorphous interface layer 28 is preferably an oxide formed by the oxidation of the surface of substrate 22, and more preferably is composed of a silicon oxide. The thickness of layer 28 is sufficient to relieve strain attributed to mismatches between the lattice constants of substrate 22 and accommodating buffer layer 24. Typically, layer 28 has a thickness in the range of approximately 0.5-5 nm.

The material for monocrystalline material layer 26 can be selected, as desired, for a particular structure or application. For example, the monocrystalline material of layer 26 may comprise a compound semiconductor which can be selected, as needed for a particular semiconductor structure, from any of the Group IIIA and VA elements (MV semiconductor compounds), mixed III-V compounds, Group II(A or B) and VIA elements (II-VI semiconductor compounds), and mixed II-VI compounds. Examples include gallium arsenide (GaAs), gallium indium arsenide (GaInAs), gallium aluminum arsenide (GaAlAs), indium phosphide (InP), cadmium sulfide (CdS), cadmium mercury telluride (CdHgTe), zinc selenide (ZnSe), zinc sulfur selenide (ZnSSe), and the like. However, monocrystalline material layer 26 may also comprise other semiconductor materials, metals, or non-metal materials which are used in the formation of semiconductor structures, devices and/or integrated circuits.

Appropriate materials for template 30 are discussed below. Suitable template materials chemically bond to the surface of the accommodating buffer layer 24 at selected sites and provide sites for the nucleation of the epitaxial growth of monocrystalline material layer 26. When used, template layer 30 has a thickness ranging from about 1 to about 10 monolayers.

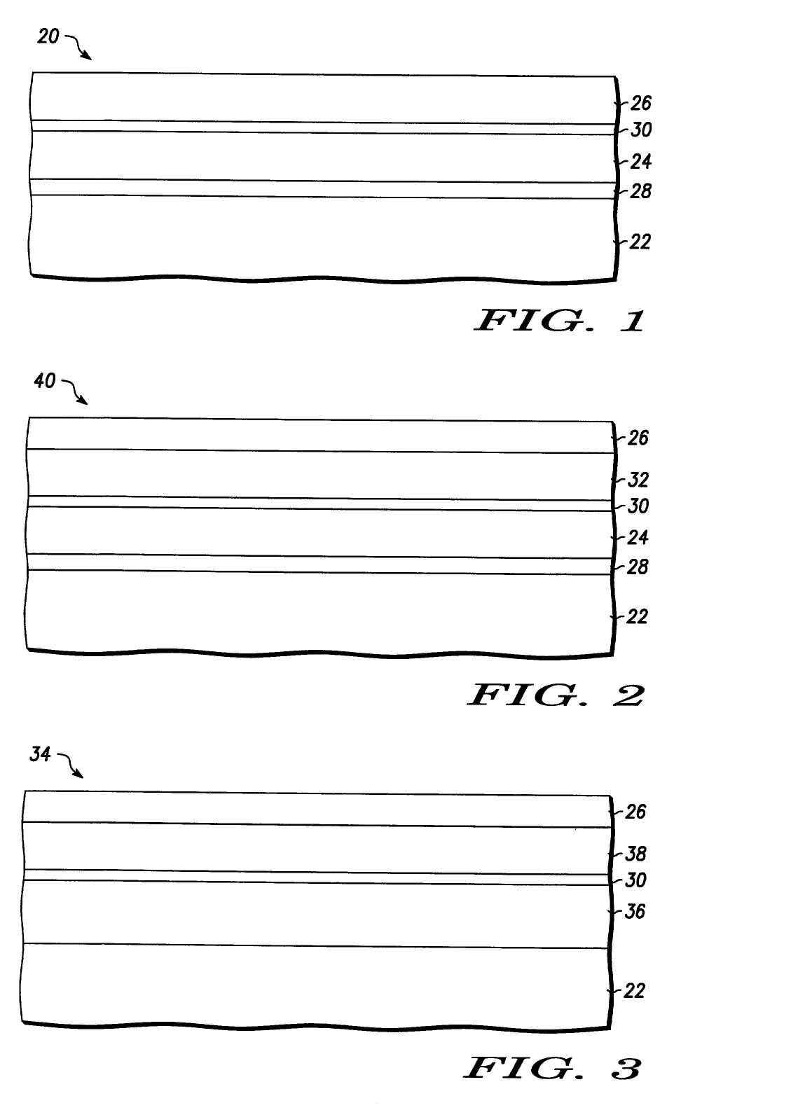

FIG. 2 illustrates, in cross section, a portion of a semiconductor structure 40 in accordance with a further embodiment of the invention. Structure 40 is similar to the previously described semiconductor structure 20, except that an additional buffer layer 32 is positioned between accommodating buffer layer 24 and monocrystalline material layer 26. Specifically, the additional buffer layer is positioned between template layer 30 and the overlying layer of monocrystalline material. The additional buffer layer, formed of a semiconductor or compound semiconductor material when the monocrystalline material layer 26 comprises a semiconductor or compound semiconductor material, serves to provide a lattice compensation when the lattice constant of the accommodating buffer layer cannot be adequately matched to the overlying monocrystalline semiconductor or compound semiconductor material layer.

FIG. 3 schematically illustrates, in cross section, a portion of a semiconductor structure 34 in accordance with another exemplary embodiment of the invention. Structure 34 is similar to structure 20, except that structure 34 includes an amorphous layer 36, rather than accommodating buffer layer 24 and amorphous interface layer 28, and an additional monocrystalline layer 38.

As explained in greater detail below, amorphous layer 36 may be formed by first forming an accommodating buffer layer and an amorphous interface layer in a similar manner to that described above. Monocrystalline layer 38 is then formed (by epitaxial growth) overlying the monocrystalline accommodating buffer layer. The accommodating buffer layer is then exposed to an anneal process to convert the monocrystalline accommodating buffer layer to an amorphous layer. Amorphous layer 36 formed in this manner comprises materials from both the accommodating buffer and interface layers, which amorphous layers may or may not amalgamate. Thus, layer 36 may comprise one or two amorphous layers. Formation of amorphous layer 36 between substrate 22 and additional monocrystalline layer 26 (subsequent to layer 38 formation) relieves stresses between layers 22 and 38 and provides a true compliant substrate for subsequent processing—e.g., monocrystalline material layer 26 formation.

The processes previously described above in connection with FIGS. 1 and 2 are adequate for growing monocrystalline material layers over a monocrystalline substrate. However, the process described in connection with FIG. 3, which includes transforming a monocrystalline accommodating buffer layer to an amorphous oxide layer, may be better for growing monocrystalline material layers because it allows any strain in layer 26 to relax.

Additional monocrystalline layer 38 may include any of the materials described throughout this application in connection with either of monocrystalline material layer 26 or additional buffer layer 32. For example, when monocrystalline material layer 26 comprises a semiconductor or compound semiconductor material, layer 38 may include monocrystalline Group IV or monocrystalline compound semiconductor materials.

In accordance with one embodiment of the present invention, additional monocrystalline layer 38 serves as an anneal cap during layer 36 formation and as a template for subsequent monocrystalline layer 26 formation. Accordingly, layer 38 is preferably thick enough to provide a suitable template for layer 26 growth (at least one monolayer) and thin enough to allow layer 38 to form as a substantially defect free monocrystalline material.

In accordance with another embodiment of the invention, additional monocrystalline layer 38 comprises monocrystalline material (e.g., a material discussed above in connection with monocrystalline layer 26) that is thick enough to form devices within layer 38. In this case, a semiconductor structure in accordance with the present invention does not include monocrystalline material layer 26. In other words, the semiconductor structure in accordance with this embodiment only includes one monocrystalline layer disposed above amorphous oxide layer 36.

The following non-limiting, illustrative examples illustrate various combinations of materials useful in structures 20, 40, and 34 in accordance with various alternative embodiments of the invention. These examples are merely illustrative, and it is not intended that the invention be limited to these illustrative examples.

### EXAMPLE 1

In accordance with one embodiment of the invention, monocrystalline substrate 22 is a silicon substrate oriented in the (100) direction. The silicon substrate can be, for example, a silicon substrate as is commonly used in making complementary metal oxide semiconductor (CMOS) integrated circuits having a diameter of about 200-300 mm. In accordance with this embodiment of the invention, accommodating buffer layer 24 is a monocrystalline layer of Sr_{z}Ba_{1-z}TiO₃ where z ranges from 0 to 1 and the amorphous intermediate layer is a layer of silicon oxide (SiOₓ) formed at the interface between the silicon substrate and the accommodating buffer layer. The value of z is selected to obtain one or more lattice constants closely matched to corresponding lattice constants of the subsequently formed layer 26. The accommodating buffer layer can have a thickness of about 2 to about 100 nanometers (nm) and preferably has a thickness of about 5 nm. In general, it is desired to have an accommodating buffer layer thick enough to isolate the monocrystalline material layer 26 from the substrate to obtain the desired electrical and optical properties. Layers thicker than 100 nm usually provide little additional benefit while increasing cost unnecessarily; however, thicker layers may be fabricated if needed. The amorphous intermediate layer of silicon oxide can have a thickness of about 0.5-5 nm, and preferably a thickness of about 1 to 2 nm. In accordance with this embodiment of the invention, monocrystalline material layer 26 is a compound semiconductor layer of gallium arsenide (GaAs) or aluminum gallium arsenide (AlGaAs) having a thickness of about 1 nm to about 100 micrometers (μm) and preferably a thickness of about 0.5 μm to 10 μm. The thickness generally depends on the application for which the layer is being prepared. To facilitate the epitaxial growth of the gallium arsenide or aluminum gallium arsenide on the monocrystalline oxide, a template layer is formed by capping the oxide layer. The template layer is preferably 1-10 monolayers of Ti—As, Sr—O—As, Sr—Ga—O, or Sr—Al—O. By way of a preferred example, 1-2 monolayers of Ti—As or Sr—Ga—O have been illustrated to successfully grow GaAs layers.

### EXAMPLE 2

In accordance with a further embodiment of the invention, monocrystalline substrate 22 is a silicon substrate as described above. The accommodating buffer layer is a monocrystalline oxide of strontium or barium zirconate or hafnate in a cubic or orthorhombic phase with an amorphous intermediate layer of silicon oxide formed at the interface between the silicon substrate and the accommodating buffer layer. The accommodating buffer layer can have a thickness of about 2-100 nm and preferably has a thickness of at least 5 nm to ensure adequate crystalline and surface quality and is formed of a monocrystalline SrZrO₃, BaZrO₃, SrHfO₃, BaSnO₃ or BaHfO₃. For example, a monocrystalline oxide layer of BaZrO₃ can grow at a temperature of about 700 degrees C. The lattice structure of the resulting crystalline oxide exhibits a 45 degree rotation with respect to the substrate silicon lattice structure.

An accommodating buffer layer formed of these zirconate or hafnate materials is suitable for the growth of a monocrystalline material layer which comprises compound semiconductor materials in the indium phosphide (InP) system. In this system, the compound semiconductor material can be, for example, indium phosphide (InP), indium gallium arsenide (InGaAs), aluminum indium arsenide, (AlInAs), or aluminum gallium indium arsenic phosphide (AlGaInAsP), having a thickness of about 1.0 nm to 10 μm. A suitable template for this structure is 1-10 monolayers of zirconium-arsenic (Zr—As), zirconium-phosphorus (Zr—P), hafnium-arsenic (Hf—As), hafnium-phosphorus (Hf—P), strontium-oxygen-arsenic (Sr—O—As), strontium-oxygen-phosphorus (Sr—O—P), barium-oxygen-arsenic (Ba—O—As), indium-strontium-oxygen (In—Sr—O), or barium-oxygen-phosphorus (Ba—O—P), and preferably 1-2 monolayers of one of these materials. By way of an example, for a barium zirconate accommodating buffer layer, the surface is terminated with 1-2 monolayers of zirconium followed by deposition of 1-2 monolayers of arsenic to form a Zr—As template. A monocrystalline layer of the compound semiconductor material from the indium phosphide system is then grown on the template layer. The resulting lattice structure of the compound semiconductor material exhibits a 45 degree rotation with respect to the accommodating buffer layer lattice structure and a lattice mismatch to (100) InP of less than 2.5%, and preferably less than about 1.0%.

### EXAMPLE 3

In accordance with a further embodiment of the invention, a structure is provided that is suitable for the growth of an epitaxial film of a monocrystalline material comprising a II-VI material overlying a silicon substrate. The substrate is preferably a silicon wafer as described above. A suitable accommodating buffer layer material is SrₓBa₁₋ₓTiO₃, where x ranges from 0 to 1, having a thickness of about 2-100 nm and preferably a thickness of about 5-15 nm. Where the monocrystalline layer comprises a compound semiconductor material, the II-VI compound semiconductor material can be, for example, zinc selenide (ZnSe) or zinc sulfur selenide (ZnSSe). A suitable template for this material system includes 1-10 monolayers of zinc-oxygen (Zn—O) followed by 1-2 monolayers of an excess of zinc followed by the selenidation of zinc on the surface. Alternatively, a template can be, for example, 1-10 monolayers of strontium-sulfur (Sr—S) followed by the ZnSeS.

### EXAMPLE 4

This embodiment of the invention is an example of structure 40 illustrated in FIG. 2. Substrate 22, accommodating buffer layer 24, and monocrystalline material layer 26 can be similar to those described in example 1. In addition, an additional buffer layer 32 serves to alleviate any strains that might result from a mismatch of the crystal lattice of the accommodating buffer layer and the lattice of the monocrystalline material. Buffer layer 32 can be a layer of germanium or a GaAs, an aluminum gallium arsenide (AlGaAs), an indium gallium phosphide (InGaP), an aluminum gallium phosphide (AlGaP), an indium gallium arsenide (InGaAs), an aluminum indium phosphide (AlInP), a gallium arsenide phosphide (GaAsP), or an indium gallium phosphide (InGaP) strain compensated superlattice. In accordance with one aspect of this embodiment, buffer layer 32 includes a GaAsₓP₁₋ₓ superlattice, wherein the value of x ranges from 0 to 1. In accordance with another aspect, buffer layer 32 includes an In_{y}Ga_{1-y}P superlattice, wherein the value of y ranges from 0 to 1. By varying the value of x or y, as the case may be, the lattice constant is varied from bottom to top across the superlattice to create a match between lattice constants of the underlying oxide and the overlying monocrystalline material which in this example is a compound semiconductor material. The compositions of other compound semiconductor materials, such as those listed above, may also be similarly varied to manipulate the lattice constant of layer 32 in a like manner. The superlattice can have a thickness of about 50-500 nm and preferably has a thickness of about 100-200 nm. The template for this structure can be the same of that described in example 1. Alternatively, buffer layer 32 can be a layer of monocrystalline germanium having a thickness of 1-50 nm and preferably having a thickness of about 2-20 nm. In using a germanium buffer layer, a template layer of either germanium-strontium (Ge—Sr) or germanium-titanium (Ge—Ti) having a thickness of about one monolayer can be used as a nucleating site for the subsequent growth of the monocrystalline material layer which in this example is a compound semiconductor material. The formation of the oxide layer is capped with either a monolayer of strontium or a monolayer of titanium to act as a nucleating site for the subsequent deposition of the monocrystalline germanium. The monolayer of strontium or titanium provides a nucleating site to which the first monolayer of germanium can bond.

### EXAMPLE 5

This example also illustrates materials useful in a structure 40 as illustrated in FIG. 2. Substrate material 22, accommodating buffer layer 24, monocrystalline material layer 26 and template layer 30 can be the same as those described above in example 2. In addition, additional buffer layer 32 is inserted between the accommodating buffer layer and the overlying monocrystalline material layer. The buffer layer, a further monocrystalline material which in this instance comprises a semiconductor material, can be, for example, a graded layer of indium gallium arsenide (InGaAs) or indium aluminum arsenide (InAlAs). In accordance with one aspect of this embodiment, additional buffer layer 32 includes InGaAs, in which the indium composition varies from 0 to about 50%. The additional buffer layer 32 preferably has a thickness of about 10-30 nm. Varying the composition of the buffer layer from GaAs to InGaAs serves to provide a lattice match between the underlying monocrystalline oxide material and the overlying layer of monocrystalline material which in this example is a compound semiconductor material. Such a buffer layer is especially advantageous if there is a lattice mismatch between accommodating buffer layer 24 and monocrystalline material layer 26.

### EXAMPLE 6

This example provides exemplary materials useful in structure 34, as illustrated in FIG. 3. Substrate material 22, template layer 30, and monocrystalline material layer 26 may be the same as those described above in connection with example 1.

Amorphous layer 36 is an amorphous oxide layer which is suitably formed of a combination of amorphous intermediate layer materials (e.g., layer 28 materials as described above) and accommodating buffer layer materials (e.g., layer 24 materials as described above). For example, amorphous layer 36 may include a combination of SiOₓ and Sr_{z}Ba_{1-z}TiO₃ (where z ranges from 0 to 1),which combine or mix, at least partially, during an anneal process to form amorphous oxide layer 36.

The thickness of amorphous layer 36 may vary from application to application and may depend on such factors as desired insulating properties of layer 36, type of monocrystalline material comprising layer 26, and the like. In accordance with one exemplary aspect of the present embodiment, layer 36 thickness is about 2 nm to about 100 nm, preferably about 2-10 nm, and more preferably about 5-6 nm.

Layer 38 comprises a monocrystalline material that can be grown epitaxially over a monocrystalline oxide material such as material used to form accommodating buffer layer 24. In accordance with one embodiment of the invention, layer 38 includes the same materials as those comprising layer 26. For example, if layer 26 includes GaAs, layer 38 also includes GaAs. However, in accordance with other embodiments of the present invention, layer 38 may include materials different from those used to form layer 26. In accordance with one exemplary embodiment of the invention, layer 38 is about 1 monolayer to about 100 nm thick.

Referring again to FIGS. 1-3, substrate 22 is a monocrystalline substrate such as a monocrystalline silicon or gallium arsenide substrate. The crystalline structure of the monocrystalline substrate is characterized by a lattice constant and by a lattice orientation. In similar manner, accommodating buffer layer 24 is also a monocrystalline material and the lattice of that monocrystalline material is characterized by a lattice constant and a crystal orientation. The lattice constants of the accommodating buffer layer and the monocrystalline substrate must be closely matched or, alternatively, must be such that upon rotation of one crystal orientation with respect to the other crystal orientation, a substantial match in lattice constants is achieved. In this context the terms “substantially equal” and “substantially matched” mean that there is sufficient similarity between the lattice constants to permit the growth of a high quality crystalline layer on the underlying layer.

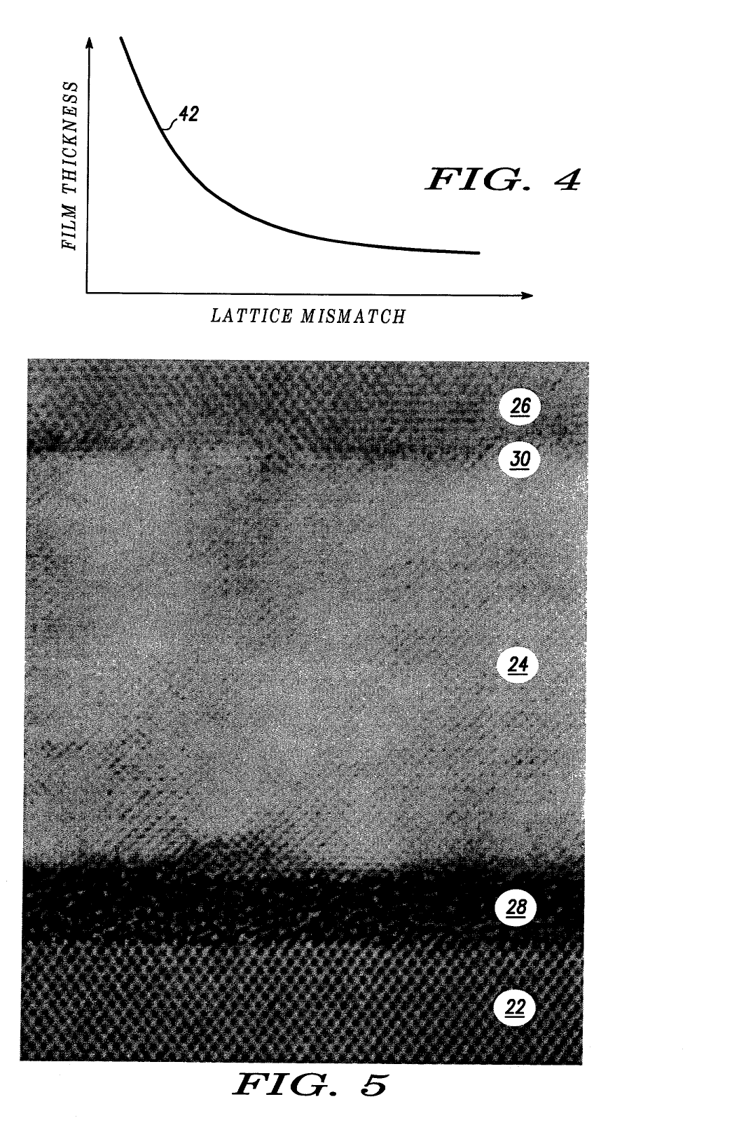

FIG. 4 illustrates graphically the relationship of the achievable thickness of a grown crystal layer of high crystalline quality as a function of the mismatch between the lattice constants of the host crystal and the grown crystal. Curve 42 illustrates the boundary of high crystalline quality material. The area to the right of curve 42 represents layers that have a large number of defects. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved.

In accordance with one embodiment of the invention, substrate 22 is a (100) or (111) oriented monocrystalline silicon wafer and accommodating buffer layer 24 is a layer of strontium barium titanate. Substantial matching of lattice constants between these two materials is achieved by rotating the crystal orientation of the titanate material by 45° with respect to the crystal orientation of the silicon substrate wafer. The inclusion in the structure of amorphous interface layer 28, a silicon oxide layer in this example, if it is of sufficient thickness, serves to reduce strain in the titanate monocrystalline layer that might result from any mismatch in the lattice constants of the host silicon wafer and the grown titanate layer. As a result, in accordance with an embodiment of the invention, a high quality, thick, monocrystalline titanate layer is achievable.

Still referring to FIGS. 1-3, layer 26 is a layer of epitaxially grown monocrystalline material and that crystalline material is also characterized by a crystal lattice constant and a crystal orientation. In accordance with one embodiment of the invention, the lattice constant of layer 26 differs from the lattice constant of substrate 22. To achieve high crystalline quality in this epitaxially grown monocrystalline layer, the accommodating buffer layer must be of high crystalline quality. In addition, in order to achieve high crystalline quality in layer 26, substantial matching between the crystal lattice constant of the host crystal, in this case, the monocrystalline accommodating buffer layer, and the grown crystal is desired. With properly selected materials this substantial matching of lattice constants is achieved as a result of rotation of the crystal orientation of the grown crystal with respect to the orientation of the host crystal. For example, if the grown crystal is gallium arsenide, aluminum gallium arsenide, zinc selenide, or zinc sulfur selenide and the accommodating buffer layer is monocrystalline SrₓBa₁₋ₓTiO₃, substantial matching of crystal lattice constants of the two materials is achieved, wherein the crystal orientation of the grown layer is rotated by 45° with respect to the orientation of the host monocrystalline oxide. Similarly, if the host material is a strontium or barium zirconate or a strontium or barium hafnate or barium tin oxide and the compound semiconductor layer is indium phosphide or gallium indium arsenide or aluminum indium arsenide, substantial matching of crystal lattice constants can be achieved by rotating the orientation of the grown crystal layer by 45° with respect to the host oxide crystal. In some instances, a crystalline semiconductor buffer layer between the host oxide and the grown monocrystalline material layer can be used to reduce strain in the grown monocrystalline material layer that might result from small differences in lattice constants. Better crystalline quality in the grown monocrystalline material layer can thereby be achieved.

The following example illustrates a process, in accordance with one embodiment of the invention, for fabricating a semiconductor structure such as the structures depicted in FIGS. 1-3. The process starts by providing a monocrystalline semiconductor substrate comprising silicon or germanium. In accordance with a preferred embodiment of the invention, the semiconductor substrate is a silicon wafer having a (100) orientation. The substrate is preferably oriented on axis or, at most, about 4° off axis. At least a portion of the semiconductor substrate has a bare surface, although other portions of the substrate, as described below, may encompass other structures. The term “bare” in this context means that the surface in the portion of the substrate has been cleaned to remove any oxides, contaminants, or other foreign material. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process in accordance with the invention. In order to epitaxially grow a monocrystalline oxide layer overlying the monocrystalline substrate, the native oxide layer must first be removed to expose the crystalline structure of the underlying substrate. The following process is preferably carried out by molecular beam epitaxy (MBE), although other epitaxial processes may also be used in accordance with the present invention. The native oxide can be removed by first thermally depositing a thin layer of strontium, barium, a combination of strontium and barium, or other alkaline earth metals or combinations of alkaline earth metals in an MBE apparatus. In the case where strontium is used, the substrate is then heated to a temperature of about 750° C. to cause the strontium to react with the native silicon oxide layer. The strontium serves to reduce the silicon oxide to leave a silicon oxide-free surface. The resultant surface, which exhibits an ordered 2×1 structure, includes strontium, oxygen, and silicon. The ordered 2×1 structure forms a template for the ordered growth of an overlying layer of a monocrystalline oxide. The template provides the necessary chemical and physical properties to nucleate the crystalline growth of an overlying layer.

In accordance with an alternate embodiment of the invention, the native silicon oxide can be converted and the substrate surface can be prepared for the growth of a monocrystalline oxide layer by depositing an alkaline earth metal oxide, such as strontium oxide, strontium barium oxide, or barium oxide, onto the substrate surface by MBE at a low temperature and by subsequently heating the structure to a temperature of about 750° C. At this temperature a solid state reaction takes place between the strontium oxide and the native silicon oxide causing the reduction of the native silicon oxide and leaving an ordered 2×1 structure with strontium, oxygen, and silicon remaining on the substrate surface. Again, this forms a template for the subsequent growth of an ordered monocrystalline oxide layer.

Following the removal of the silicon oxide from the surface of the substrate, in accordance with one embodiment of the invention, the substrate is cooled to a temperature in the range of about 200-800° C. and a layer of strontium titanate is grown on the template layer by molecular beam epitaxy. The MBE process is initiated by opening shutters in the MBE apparatus to expose strontium, titanium and oxygen sources. The ratio of strontium and titanium is approximately 1:1. The partial pressure of oxygen is initially set at a minimum value to grow stoichiometric strontium titanate at a growth rate of about 0.3-0.5 nm per minute. After initiating growth of the strontium titanate, the partial pressure of oxygen is increased above the initial minimum value. The overpressure of oxygen causes the growth of an amorphous silicon oxide layer at the interface between the underlying substrate and the growing strontium titanate layer. The growth of the silicon oxide layer results from the diffusion of oxygen through the growing strontium titanate layer to the interface where the oxygen reacts with silicon at the surface of the underlying substrate. The strontium titanate grows as an ordered (100) monocrystal with the (100) crystalline orientation rotated by 45° with respect to the underlying substrate. Strain that otherwise might exist in the strontium titanate layer because of the small mismatch in lattice constant between the silicon substrate and the growing crystal is relieved in the amorphous silicon oxide intermediate layer.

After the strontium titanate layer has been grown to the desired thickness, the monocrystalline strontium titanate is capped by a template layer that is conducive to the subsequent growth of an epitaxial layer of a desired monocrystalline material. For example, for the subsequent growth of a monocrystalline compound semiconductor material layer of gallium arsenide, the MBE growth of the strontium titanate monocrystalline layer can be capped by terminating the growth with 1-2 monolayers of titanium, 1-2 monolayers of titanium-oxygen or with 1-2 monolayers of strontium-oxygen. Following the formation of this capping layer, arsenic is deposited to form a Ti—As bond, a Ti—O—As bond or a Sr—O—As. Any of these form an appropriate template for deposition and formation of a gallium arsenide monocrystalline layer. Following the formation of the template, gallium is subsequently introduced to the reaction with the arsenic and gallium arsenide forms. Alternatively, gallium can be deposited on the capping layer to form a Sr—O—Ga bond, and arsenic is subsequently introduced with the gallium to form the GaAs.

FIG. 5 is a high resolution Transmission Electron Micrograph (TEM) of semiconductor material manufactured in accordance with one embodiment of the present invention. Single crystal SrTiO₃ accommodating buffer layer 24 was grown epitaxially on silicon substrate 22. During this growth process, amorphous interfacial layer 28 is formed which relieves strain due to lattice mismatch. GaAs compound semiconductor layer 26 was then grown epitaxially using template layer 30.

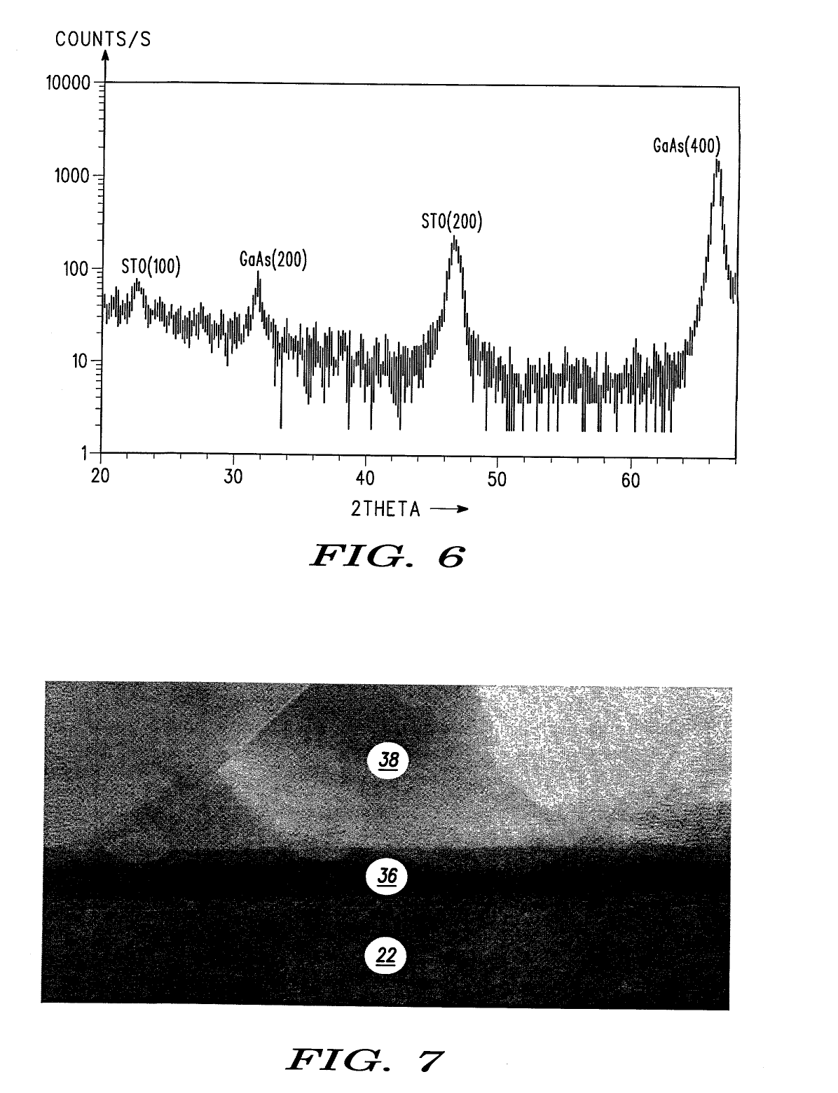

FIG. 6 illustrates an x-ray diffraction spectrum taken on a structure including GaAs monocrystalline layer 26 comprising GaAs grown on silicon substrate 22 using accommodating buffer layer 24. The peaks in the spectrum indicate that both the accommodating buffer layer 24 and GaAs compound semiconductor layer 26 are single crystal and (100) orientated.

The structure illustrated in FIG. 2 can be formed by the process discussed above with the addition of an additional buffer layer deposition step. The additional buffer layer 32 is formed overlying the template layer before the deposition of the monocrystalline material layer. If the buffer layer is a monocrystalline material comprising a compound semiconductor superlattice, such a superlattice can be deposited, by MBE for example, on the template described above. If instead the buffer layer is a monocrystalline material layer comprising a layer of germanium, the process above is modified to cap the strontium titanate monocrystalline layer with a final layer of either strontium or titanium and then by depositing germanium to react with the strontium or titanium. The germanium buffer layer can then be deposited directly on this template.

Structure 34, illustrated in FIG. 3, may be formed by growing an accommodating buffer layer, forming an amorphous oxide layer over substrate 22, and growing semiconductor layer 38 over the accommodating buffer layer, as described above. The accommodating buffer layer and the amorphous oxide layer are then exposed to an anneal process sufficient to change the crystalline structure of the accommodating buffer layer from monocrystalline to amorphous, thereby forming an amorphous layer such that the combination of the amorphous oxide layer and the now amorphous accommodating buffer layer form a single amorphous oxide layer 36. Layer 26 is then subsequently grown over layer 38. Alternatively, the anneal process may be carried out subsequent to growth of layer 26.

In accordance with one aspect of this embodiment, layer 36 is formed by exposing substrate 22, the accommodating buffer layer, the amorphous oxide layer, and monocrystalline layer 38 to a rapid thermal anneal process with a peak temperature of about 700° C. to about 1000° C. and a process time of about 5 seconds to about 10 minutes. However, other suitable anneal processes may be employed to convert the accommodating buffer layer to an amorphous layer in accordance with the present invention. For example, laser annealing, electron beam annealing, or “conventional” thermal annealing processes (in the proper environment) may be used to form layer 36. When conventional thermal annealing is employed to form layer 36, an overpressure of one or more constituents of layer 30 may be required to prevent degradation of layer 38 during the anneal process. For example, when layer 38 includes GaAs, the anneal environment preferably includes an overpressure of arsenic to mitigate degradation of layer 38.

As noted above, layer 38 of structure 34 may include any materials suitable for either of layers 32 or 26. Accordingly, any deposition or growth methods described in connection with either layer 32 or 26, may be employed to deposit layer 38.

FIG. 7 is a high resolution TEM of semiconductor material manufactured in accordance with the embodiment of the invention illustrated in FIG. 3. In accordance with this embodiment, a single crystal SrTiO₃ accommodating buffer layer was grown epitaxially on silicon substrate 22. During this growth process, an amorphous interfacial layer forms as described above. Next, additional monocrystalline layer 38 comprising a compound semiconductor layer of GaAs is formed above the accommodating buffer layer and the accommodating buffer layer is exposed to an anneal process to form amorphous oxide layer 36.

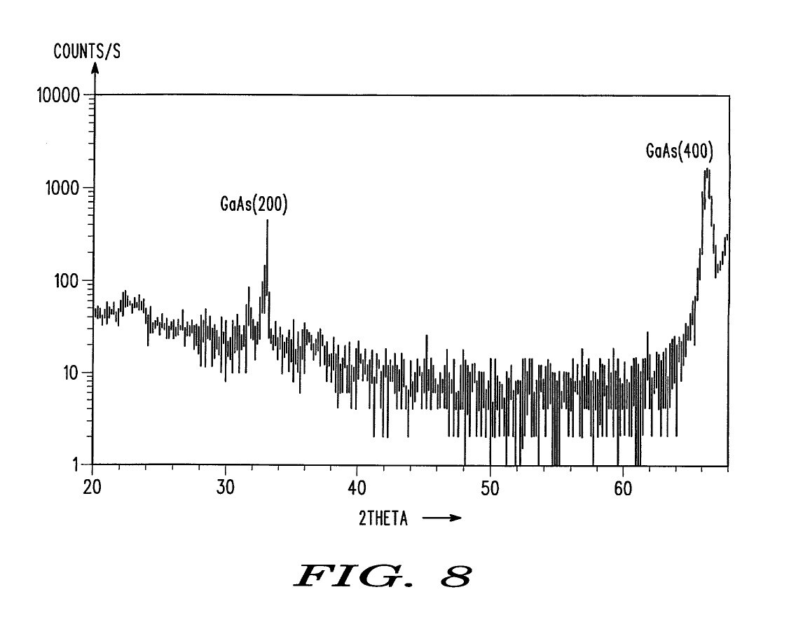

FIG. 8 illustrates an x-ray diffraction spectrum taken on a structure including additional monocrystalline layer 38 comprising a GaAs compound semiconductor layer and amorphous oxide layer 36 formed on silicon substrate 22. The peaks in the spectrum indicate that GaAs compound semiconductor layer 38 is single crystal and (100) orientated and the lack of peaks around 40 to 50 degrees indicates that layer 36 is amorphous.

The process described above illustrates a process for forming a semiconductor structure including a silicon substrate, an overlying oxide layer, and a monocrystalline material layer comprising a gallium arsenide compound semiconductor layer by the process of molecular beam epitaxy. The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Further, by a similar process, other monocrystalline accommodating buffer layers such as alkaline earth metal titanates, zirconates, hafnates, tantalates, vanadates, ruthenates, and niobates, alkaline earth metal tin-based perovskites, lanthanum aluminate, lanthanum scandium oxide, and gadolinium oxide can also be grown. Further, by a similar process such as MBE, other monocrystalline material layers comprising other III-V and II-VI monocrystalline compound semiconductors, semiconductors, metals and non-metals can be deposited overlying the monocrystalline oxide accommodating buffer layer.

Each of the variations of monocrystalline material layer and monocrystalline oxide accommodating buffer layer uses an appropriate template for initiating the growth of the monocrystalline material layer. For example, if the accommodating buffer layer is an alkaline earth metal zirconate, the oxide can be capped by a thin layer of zirconium. The deposition of zirconium can be followed by the deposition of arsenic or phosphorus to react with the zirconium as a precursor to depositing indium gallium arsenide, indium aluminum arsenide, or indium phosphide respectively. Similarly, if the monocrystalline oxide accommodating buffer layer is an alkaline earth metal hafnate, the oxide layer can be capped by a thin layer of hafnium. The deposition of hafnium is followed by the deposition of arsenic or phosphorous to react with the hafnium as a precursor to the growth of an indium gallium arsenide, indium aluminum arsenide, or indium phosphide layer, respectively. In a similar manner, strontium titanate can be capped with a layer of strontium or strontium and oxygen and barium titanate can be capped with a layer of barium or barium and oxygen. Each of these depositions can be followed by the deposition of arsenic or phosphorus to react with the capping material to form a template for the deposition of a monocrystalline material layer comprising compound semiconductors such as indium gallium arsenide, indium aluminum arsenide, or indium phosphide.

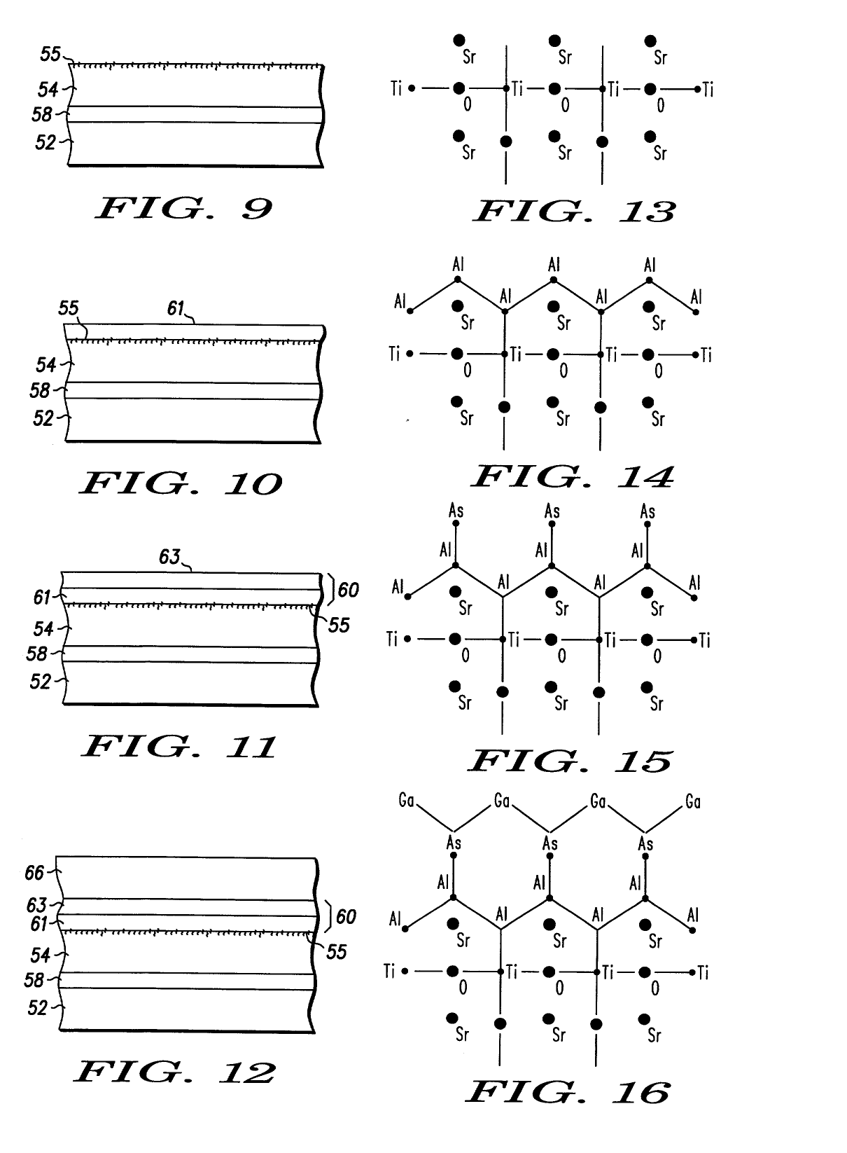

The formation of a device structure in accordance with another embodiment of the invention is illustrated schematically in cross-section in FIGS. 9-12. Like the previously described embodiments referred to in FIGS. 1-3, this embodiment of the invention involves the process of forming a compliant substrate utilizing the epitaxial growth of single crystal oxides, such as the formation of accommodating buffer layer 24 previously described with reference to FIGS. 1 and 2 and amorphous layer 36 previously described with reference to FIG. 3, and the formation of a template layer 30. However, the embodiment illustrated in FIGS. 9-12 utilizes a template that includes a surfactant to facilitate layer-by-layer monocrystalline material growth.

Turning now to FIG. 9, an amorphous intermediate layer 58 is grown on substrate 52 at the interface between substrate 52 and a growing accommodating buffer layer 54, which is preferably a monocrystalline crystal oxide layer, by the oxidation of substrate 52 during the growth of layer 54. Layer 54 is preferably a monocrystalline oxide material such as a monocrystalline layer of Sr_{z}Ba_{1-z}TiO₃ where z ranges from 0 to 1. However, layer 54 may also comprise any of those compounds previously described with reference layer 24 in FIGS. 1-2 and any of those compounds previously described with reference to layer 36 in FIG. 3 which is formed from layers 24 and 28 referenced in FIGS. 1 and 2.

Layer 54 is grown with a strontium (Sr) terminated surface represented in FIG. 9 by hatched line 55 which is followed by the addition of a template layer 60 which includes a surfactant layer 61 and capping layer 63 as illustrated in FIGS. 10 and 11. Surfactant layer 61 may comprise, but is not limited to, elements such as Al, In and Ga, but will be dependent upon the composition of layer 54 and the overlying layer of monocrystalline material for optimal results. In one exemplary embodiment, aluminum (Al) is used for surfactant layer 61 and functions to modify the surface and surface energy of layer 54. Preferably, surfactant layer 61 is epitaxially grown, to a thickness of one to two monolayers, over layer 54 as illustrated in FIG. 10 by way of molecular beam epitaxy (MBE), although other epitaxial processes may also be performed including chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like.

Surfactant layer 61 is then exposed to a Group V element such as arsenic, for example, to form capping layer 63 as illustrated in FIG. 11. Surfactant layer 61 may be exposed to a number of materials to create capping layer 63 such as elements which include, but are not limited to, As, P, Sb and N. Surfactant layer 61 and capping layer 63 combine to form template layer 60.

Monocrystalline material layer 66, which in this example is a compound semiconductor such as GaAs, is then deposited via MBE, CVD, MOCVD, MEE, ALE, PVD, CSD, PLD, and the like to form the final structure illustrated in FIG. 12.

FIGS. 13-16 illustrate possible molecular bond structures for a specific example of a compound semiconductor structure formed in accordance with the embodiment of the invention illustrated in FIGS. 9-12. More specifically, FIGS. 13-16 illustrate the growth of GaAs (layer 66) on the strontium terminated surface of a strontium titanate monocrystalline oxide (layer 54) using a surfactant containing template (layer 60).

The growth of a monocrystalline material layer 66 such as GaAs on an accommodating buffer layer 54 such as a strontium titanium oxide over amorphous interface layer 58 and substrate layer 52, both of which may comprise materials previously described with reference to layers 28 and 22, respectively in FIGS. 1 and 2, illustrates a critical thickness of about 1000 Angstroms where the two-dimensional (2D) and three-dimensional (3D) growth shifts because of the surface energies involved. In order to maintain a true layer by layer growth (Frank Van der Mere growth), the following relationship must be satisfied:

δ_{STO}>(δ_{INT}+δ_{GaAs})

where the surface energy of the monocrystalline oxide layer 54 must be greater than the surface energy of the amorphous interface layer 58 added to the surface energy of the GaAs layer 66. Since it is impracticable to satisfy this equation, a surfactant containing template was used, as described above with reference to FIGS. 10-12, to increase the surface energy of the monocrystalline oxide layer 54 and also to shift the crystalline structure of the template to a diamond-like structure that is in compliance with the original GaAs layer.

FIG. 13 illustrates the molecular bond structure of a strontium terminated surface of a strontium titanate monocrystalline oxide layer. An aluminum surfactant layer is deposited on top of the strontium terminated surface and bonds with that surface as illustrated in FIG. 14, which reacts to form a capping layer comprising a monolayer of Al₂Sr having the molecular bond structure illustrated in FIG. 14 which forms a diamond-like structure with an sp³ hybrid terminated surface that is compliant with compound semiconductors such as GaAs. The structure is then exposed to As to form a layer of AlAs as shown in FIG. 15. GaAs is then deposited to complete the molecular bond structure illustrated in FIG. 16 which has been obtained by 2D growth. The GaAs can be grown to any thickness for forming other semiconductor structures, devices, or integrated circuits. Alkaline earth metals such as those in Group IIA are those elements preferably used to form the capping surface of the monocrystalline oxide layer 54 because they are capable of forming a desired molecular structure with aluminum.

In this embodiment, a surfactant containing template layer aids in the formation of a compliant substrate for the monolithic integration of various material layers including those comprised of Group III-V compounds to form high quality semiconductor structures, devices and integrated circuits. For example, a surfactant containing template may be used for the monolithic integration of a monocrystalline material layer such as a layer comprising Germanium (Ge), for example, to form high efficiency photocells.

Turning now to FIGS. 17-20, the formation of a device structure in accordance with still another embodiment of the invention is illustrated in cross-section. This embodiment utilizes the formation of a compliant substrate which relies on the epitaxial growth of single crystal oxides on silicon followed by the epitaxial growth of single crystal silicon onto the oxide.

An accommodating buffer layer 74 such as a monocrystalline oxide layer is first grown on a substrate layer 72, such as silicon, with an amorphous interface layer 78 as illustrated in FIG. 17. Monocrystalline oxide layer 74 may be comprised of any of those materials previously discussed with reference to layer 24 in FIGS. 1 and 2, while amorphous interface layer 78 is preferably comprised of any of those materials previously described with reference to the layer 28 illustrated in FIGS. 1 and 2. Substrate 72, although preferably silicon, may also comprise any of those materials previously described with reference to substrate 22 in FIGS. 1-3.

Next, a silicon layer 81 is deposited over monocrystalline oxide layer 74 via MBE, CVD, MOCVD, MEE, ALE, PVD, CSD, PLD, and the like as illustrated in FIG. 18 with a thickness of a few hundred Angstroms but preferably with a thickness of about 50 Angstroms. Monocrystalline oxide layer 74 preferably has a thickness of about 20 to 100 Angstroms.

Rapid thermal annealing is then conducted in the presence of a carbon source such as acetylene or methane, for example at a temperature within a range of about 800° C. to 1000° C. to form capping layer 82 and silicate amorphous layer 86. However, other suitable carbon sources may be used as long as the rapid thermal annealing step functions to amorphize the monocrystalline oxide layer74 into a silicate amorphous layer 86 and carbonize the top silicon layer 81 to form capping layer 82 which in this example would be a silicon carbide (SiC) layer as illustrated in FIG. 19. The formation of amorphous layer 86 is similar to the formation of layer 36 illustrated in FIG. 3 and may comprise any of those materials described with reference to layer 36 in FIG. 3 but the preferable material will be dependent upon the capping layer 82 used for silicon layer 81.

Finally, a compound semiconductor layer 96, such as gallium nitride (GaN) is grown over the SiC surface by way of MBE, CVD, MOCVD, MEE, ALE, PVD, CSD, PLD, or the like to form a high quality compound semiconductor material for device formation. More specifically, the deposition of GaN and GaN based systems such as GaInN and AlGaN will result in the formation of dislocation nets confined at the silicon/amorphous region. The resulting nitride containing compound semiconductor material may comprise elements from groups III, IV and V of the periodic table and is defect free.

Although GaN has been grown on SiC substrate in the past, this embodiment of the invention possesses a one step formation of the compliant substrate containing a SiC top surface and an amorphous layer on a Si surface. More specifically, this embodiment of the invention uses an intermediate single crystal oxide layer that is amorphosized to form a silicate layer which adsorbs the strain between the layers. Moreover, unlike past use of a SiC substrate, this embodiment of the invention is not limited by wafer size which is usually less than 50 mm in diameter for prior art SiC substrates.

The monolithic integration of nitride containing semiconductor compounds containing group III-V nitrides and silicon devices can be used for high temperature RF applications and optoelectronics. GaN systems have particular use in the photonic industry for the blue/green and UV light sources and detection. High brightness light emitting diodes (LEDs) and lasers may also be formed within the GaN system.

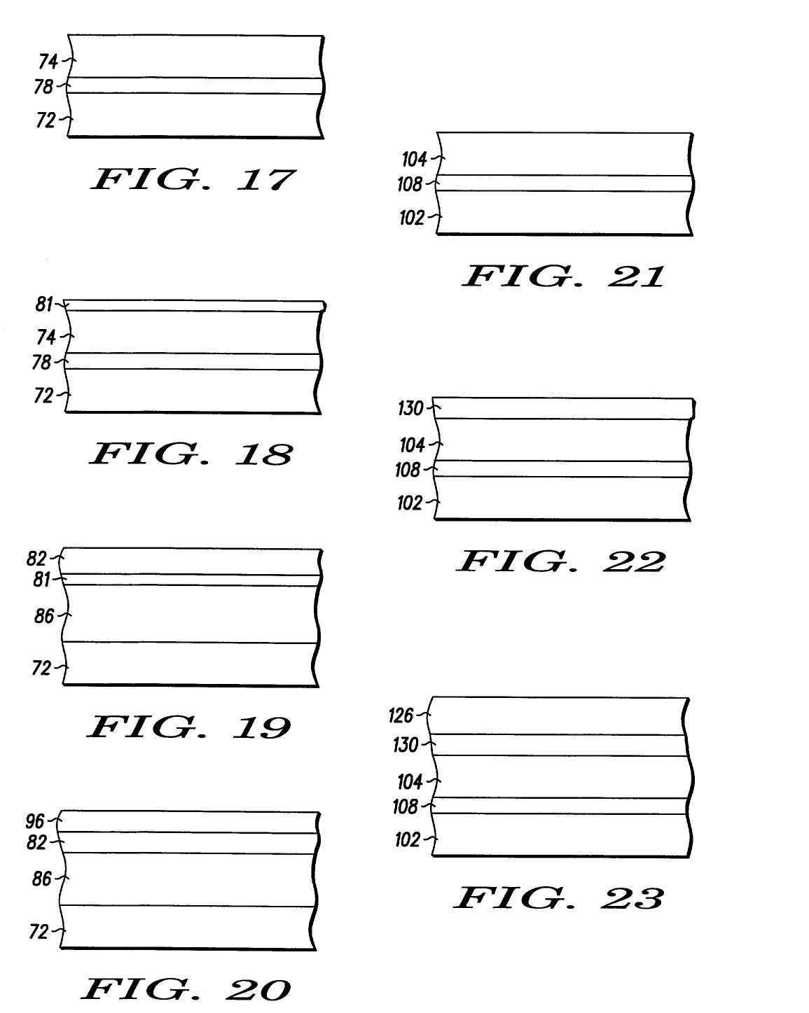

FIGS. 21-23 schematically illustrate, in cross-section, the formation of another embodiment of a device structure in accordance with the invention. This embodiment includes a compliant layer that functions as a transition layer that uses clathrate or Zintl type bonding. More specifically, this embodiment utilizes an intermetallic template layer to reduce the surface energy of the interface between material layers thereby allowing for two dimensional layer by layer growth.

The structure illustrated in FIG. 21 includes a monocrystalline substrate 102, an amorphous interface layer 108 and an accommodating buffer layer 104. Amorphous interface layer 108 is formed on substrate 102 at the interface between substrate 102 and accommodating buffer layer 104 as previously described with reference to FIGS. 1 and 2. Amorphous interface layer 108 may comprise any of those materials previously described with reference to amorphous interface layer 28 in FIGS. 1 and 2. Substrate 102 is preferably silicon but may also comprise any of those materials previously described with reference to substrate 22 in FIGS. 1-3.

A template layer 130 is deposited over accommodating buffer layer 104 as illustrated in FIG. 22 and preferably comprises a thin layer of Zintl type phase material composed of metals and metalloids having a great deal of ionic character. As in previously described embodiments, template layer 130 is deposited by way of MBE, CVD, MOCVD, MEE, ALE, PVD, CSD, PLD, or the like to achieve a thickness of one monolayer. Template layer 130 functions as a “soft” layer with non-directional bonding but high crystallinity which absorbs stress build up between layers having lattice mismatch. Materials for template 130 may include, but are not limited to, materials containing Si, Ga, In, and Sb such as, for example, AlSr₂, (MgCaYb)Ga₂, (Ca,Sr,Eu,Yb)In₂, BaGe₂As, and SrSn₂As₂

A monocrystalline material layer 126 is epitaxially grown over template layer 130 to achieve the final structure illustrated in FIG. 23. As a specific example, an SrAl₂ layer may be used as template layer 130 and an appropriate monocrystalline material layer 126 such as a compound semiconductor material GaAs is grown over the SrAl₂. The Al—Ti (from the accommodating buffer layer of layer of Sr_{z}Ba_{1-z}TiO₃ where z ranges from 0 to 1) bond is mostly metallic while the Al—As (from the GaAs layer) bond is weakly covalent. The Sr participates in two distinct types of bonding with part of its electric charge going to the oxygen atoms in the lower accommodating buffer layer 104 comprising Sr_{z}Ba_{1-z}TiO₃ to participate in ionic bonding and the other part of its valence charge being donated to Al in a way that is typically carried out with Zintl phase materials. The amount of the charge transfer depends on the relative electro negativity of elements comprising the template layer 130 as well as on the interatomic distance. In this example, Al assumes an sp hybridization and can readily form bonds with monocrystalline material layer 126, which in this example, comprises compound semiconductor material GaAs.

The compliant substrate produced by use of the Zintl type template layer used in this embodiment can absorb a large strain without a significant energy cost. In the above example, the bond strength of the Al is adjusted by changing the volume of the SrAl₂ layer thereby making the device tunable for specific applications which include the monolithic integration of III-V and Si devices and the monolithic integration of high-k dielectric materials for CMOS technology.

Clearly, those embodiments specifically describing structures having compound semiconductor portions and Group IV semiconductor portions, are meant to illustrate embodiments of the present invention and not limit the present invention. There are a multiplicity of other combinations and other embodiments of the present invention. For example, the present invention includes structures and methods for fabricating material layers which form semiconductor structures, devices and integrated circuits including other layers such as metal and non-metal layers. More specifically, the invention includes structures and methods for forming a compliant substrate which is used in the fabrication of semiconductor structures, devices and integrated circuits and the material layers suitable for fabricating those structures, devices, and integrated circuits. By using embodiments of the present invention, it is now simpler to integrate devices that include monocrystalline layers comprising semiconductor and compound semiconductor materials as well as other material layers that are used to form those devices with other components that work better or are easily and/or inexpensively formed within semiconductor or compound semiconductor materials. This allows a device to be shrunk, the manufacturing costs to decrease, and yield and reliability to increase.

In accordance with one embodiment of this invention, a monocrystalline semiconductor or compound semiconductor wafer can be used in forming monocrystalline material layers over the wafer. In this manner, the wafer is essentially a “handle” wafer used during the fabrication of semiconductor electrical components within a monocrystalline layer overlying the wafer. Therefore, electrical components can be formed within semiconductor materials over a wafer of at least approximately 200 millimeters in diameter and possibly at least approximately 300 millimeters.

By the use of this type of substrate, a relatively inexpensive “handle” wafer overcomes the fragile nature of compound semiconductor or other monocrystalline material wafers by placing them over a relatively more durable and easy to fabricate base material. Therefore, an integrated circuit can be formed such that all electrical components, and particularly all active electronic devices, can be formed within or using the monocrystalline material layer even though the substrate itself may include a monocrystalline semiconductor material. Fabrication costs for compound semiconductor devices and other devices employing non-silicon monocrystalline materials should decrease because larger substrates can be processed more economically and more readily compared to the relatively smaller and more fragile substrates (e.g. conventional compound semiconductor wafers).

Any of the monolithic devices discussed above having a plurality of different semiconductor materials are used to form one or more semiconductor devices. Phased array circuits are formed by integration of these semiconductor devices. The description below for FIGS. 24-31 describe formation of some exemplary semiconductor devices. Many alternative or additional semiconductor devices now known or later developed may be formed in any one or more of the different semiconductor materials.

FIG. 24 illustrates schematically, in cross section, a device structure 50 in accordance with a further embodiment. Device structure 50 includes a monocrystalline semiconductor substrate 52, preferably a monocrystalline silicon wafer. Monocrystalline semiconductor substrate 52 includes two regions, 53 and 57. An electrical semiconductor component generally indicated by the dashed line 56 is formed, at least partially, in region 53. Electrical component 56 can be a phased array component, such as a resistor, a capacitor, an active semiconductor component (e.g. a diode or a transistor) or an integrated circuit such as a CMOS integrated circuit. For example, electrical semiconductor component 56 can be a CMOS integrated circuit configured to perform digital signal processing or another function for which silicon integrated circuits are well suited. The electrical semiconductor component in region 53 can be formed by conventional semiconductor processing as well known and widely practiced in the semiconductor industry. A layer of insulating material 59 such as a layer of silicon dioxide or the like may overlie electrical semiconductor component 56.

Insulating material 59 and any other layers that may have been formed or deposited during the processing of semiconductor component 56 in region 53 are removed from the surface of region 57 to provide a bare silicon surface in that region. As is well known, bare silicon surfaces are highly reactive and a native silicon oxide layer can quickly form on the bare surface. A layer of barium or barium and oxygen is deposited onto the native oxide layer on the surface of region 57 and is reacted with the oxidized surface to form a first template layer (not shown). In accordance with one embodiment, a monocrystalline oxide layer is formed overlying the template layer by a process of molecular beam epitaxy. Reactants including barium, titanium and oxygen are deposited onto the template layer to form the monocrystalline oxide layer. Initially during the deposition the partial pressure of oxygen is kept near the minimum necessary to fully react with the barium and titanium to form monocrystalline barium titanate layer. The partial pressure of oxygen is then increased to provide an overpressure of oxygen and to allow oxygen to diffuse through the growing monocrystalline oxide layer. The oxygen diffusing through the barium titanate reacts with silicon at the surface of region 57 to form an amorphous layer of silicon oxide 62 on second region 57 and at the interface between silicon substrate 52 and the monocrystalline oxide layer 65. Layers 65 and 62 may be subject to an annealing process as described above in connection with FIG. 3 to form a single amorphous accommodating layer.

In accordance with an embodiment, the step of depositing the monocrystalline oxide layer 65 is terminated by depositing a second template layer 64, which can be 1-10 monolayers of titanium, barium, barium and oxygen, or titanium and oxygen. A layer 66 of a monocrystalline compound semiconductor material is then deposited overlying second template layer 64 by a process of molecular beam epitaxy. The deposition of layer 66 is initiated by depositing a layer of arsenic onto template 64. This initial step is followed by depositing gallium and arsenic to form monocrystalline gallium arsenide 66. Alternatively, strontium can be substituted for barium in the above example.

In accordance with a further embodiment, a semiconductor component, generally indicated by a dashed line 68 is formed in compound semiconductor layer 66. Semiconductor component 68 can be formed by processing steps conventionally used in the fabrication of gallium arsenide or other III-V compound semiconductor material devices. Semiconductor component 68 can be any active or passive component, and preferably is a semiconductor laser, light emitting diode, photodetector, heterojunction bipolar transistor (HBT), high frequency MESFET, or other component that utilizes and takes advantage of the physical properties of compound semiconductor materials. A metallic conductor schematically indicated by the line 70 can be formed to electrically couple device 68 and device 56, thus implementing an integrated device that includes at least one component formed in silicon substrate 52 and one device formed in monocrystalline compound semiconductor material layer 66. Although illustrative structure 50 has been described as a structure formed on a silicon substrate 52 and having a barium (or strontium) titanate layer 65 and a gallium arsenide layer 66, similar devices can be fabricated using other substrates, monocrystalline oxide layers and other compound semiconductor layers as described elsewhere in this disclosure.

FIG. 25 illustrates a semiconductor structure 71 in accordance with a further embodiment. Structure 71 includes a monocrystalline semiconductor substrate 73 such as a monocrystalline silicon wafer that includes a region 75 and a region 76. An electrical component schematically illustrated by the dashed line 79 is formed in region 75 using conventional silicon device processing techniques commonly used in the semiconductor industry. Using process steps similar to those described above, a monocrystalline oxide layer 80 and an intermediate amorphous silicon oxide layer 82 are formed overlying region 76 of substrate 73. A template layer 84 and subsequently a monocrystalline semiconductor layer 87 are formed overlying monocrystalline oxide layer 80. In accordance with a further embodiment, an additional monocrystalline oxide layer 88 is formed overlying layer 87 by process steps similar to those used to form layer 80, and an additional monocrystalline semiconductor layer 90 is formed overlying monocrystalline oxide layer 88 by process steps similar to those used to form layer 87. In accordance with one embodiment, at least one of layers 87 and 90 are formed from a compound semiconductor material. Layers 80 and 83 may be subject to an annealing process as described above in connection with FIG. 3 to form a single amorphous accommodating layer.

A semiconductor component generally indicated by a dashed line 92 is formed at least partially in monocrystalline semiconductor layer 87. In accordance with one embodiment, semiconductor component 92 may include a field effect transistor having a gate dielectric formed, in part, by monocrystalline oxide layer 88. In addition, monocrystalline semiconductor layer 90 can be used to implement the gate electrode of that field effect transistor. In accordance with one embodiment, monocrystalline semiconductor layer 87 is formed from a group III-V compound and semiconductor component 92 is a radio frequency amplifier that takes advantage of the high mobility characteristic of group III-V component materials. In accordance with yet a further embodiment, an electrical interconnection schematically illustrated by the line 94 electrically interconnects component 79 and component 92. Structure 71 thus integrates components that take advantage of the unique properties of the two monocrystalline semiconductor materials.

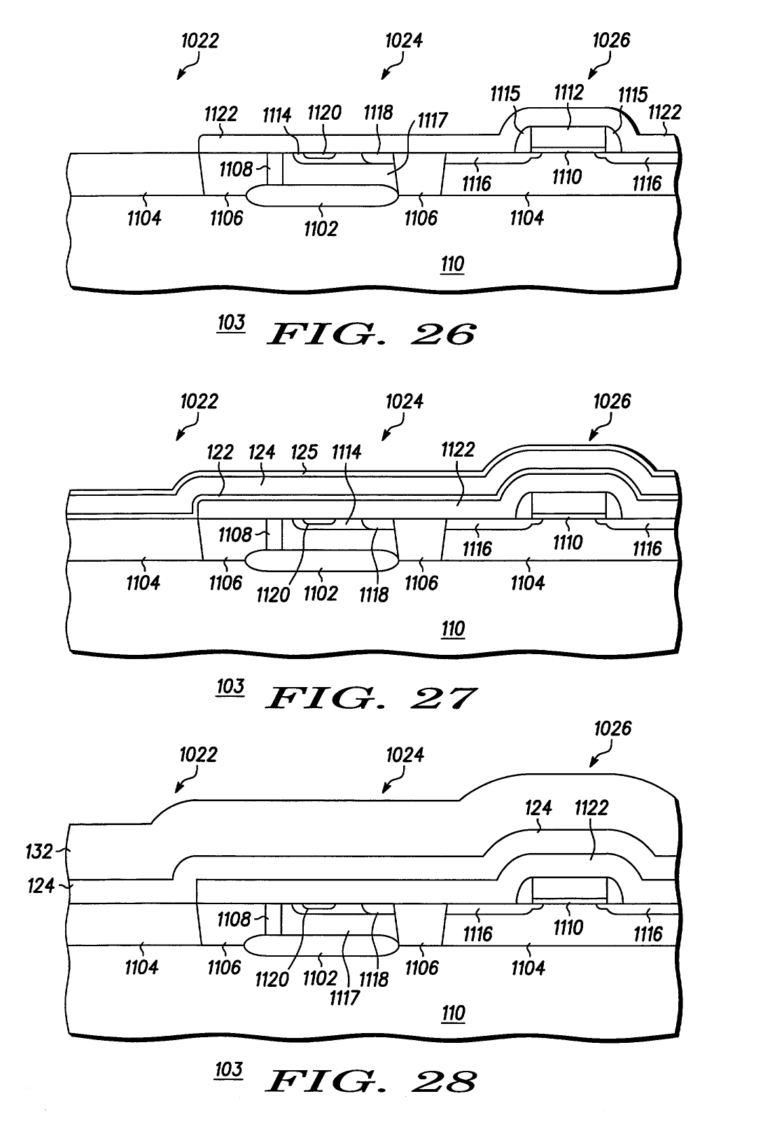

Attention is now directed to a method for forming exemplary portions of illustrative composite semiconductor structures or composite integrated circuits like 50 or 71. In particular, the illustrative composite semiconductor structure or integrated circuit 103 shown in FIGS. 26-30 includes a compound semiconductor portion 1022, a bipolar portion 1024, and a MOS portion 1026. In FIG. 26, a p-type doped, monocrystalline silicon substrate 110 is provided having a compound semiconductor portion 1022, a bipolar portion 1024, and an MOS portion 1026. Within bipolar portion 1024, the monocrystalline silicon substrate 110 is doped to form an N⁺ buried region 1102. A lightly p-type doped epitaxial monocrystalline silicon layer 1104 is then formed over the buried region 1102 and the substrate 110. A doping step is then performed to create a lightly n-type doped drift region 1117 above the N⁺ buried region 1102. The doping step converts the dopant type of the lightly p-type epitaxial layer within a section of the bipolar region 1024 to a lightly n-type monocrystalline silicon region. A field isolation region 1106 is then formed between and around the bipolar portion 1024 and the MOS portion 1026. A gate dielectric layer 1110 is formed over a portion of the epitaxial layer 1104 within MOS portion 1026, and the gate electrode 1112 is then formed over the gate dielectric layer 1110. Sidewall spacers 1115 are formed along vertical sides of the gate electrode 1112 and gate dielectric layer 1110.

A p-type dopant is introduced into the drift region 1117 to form an active or intrinsic base region 1114. An n-type, deep collector region 1108 is then formed within the bipolar portion 1024 to allow electrical connection to the buried region 1102. Selective n-type doping is performed to form N⁺ doped regions 1116 and the emitter region 1120. N⁺ doped regions 1116 are formed within layer 1104 along adjacent sides of the gate electrode 1112 and are source, drain, or source/drain regions for the MOS transistor. The N⁺ doped regions 1116 and emitter region 1120 have a doping concentration of at least 1E19 atoms per cubic centimeter to allow ohmic contacts to be formed. A p-type doped region is formed to create the inactive or extrinsic base region 1118 which is a P⁺ doped region (doping concentration of at least 1E19 atoms per cubic centimeter).

In the embodiment described, several processing steps have been performed but are not illustrated or further described, such as the formation of well regions, threshold adjusting implants, channel punchthrough prevention implants, field punchthrough prevention implants, as well as a variety of masking layers. The formation of the device up to this point in the process is performed using conventional steps. As illustrated, a standard N-channel MOS transistor has been formed within the MOS region 1026, and a vertical NPN bipolar transistor has been formed within the bipolar portion 1024. Different or additional semiconductor devices, including the same or different types of devices, in any of various combinations may be formed. Although illustrated with a NPN bipolar transistor and a N-channel MOS transistor, device structures and circuits in accordance with various embodiments may additionally or alternatively include other electronic devices formed using the silicon substrate. As of this point, no circuitry has been formed within the compound semiconductor portion 1022.

After the silicon devices are formed in regions 1024 and 1026, a protective layer 1122 is formed overlying devices in regions 1024 and 1026 to protect devices in regions 1024 and 1026 from potential damage resulting from device formation in region 1022. Layer 1122 may be formed of, for example, an insulating material such as silicon oxide or silicon nitride.

All of the layers that have been formed during the processing of the bipolar and MOS portions of the integrated circuit, except for epitaxial layer 1104 but including protective layer 1122, are now removed from the surface of compound semiconductor portion 1022. A bare silicon surface is thus provided for the subsequent processing of this portion, for example in the manner set forth above.

An accommodating buffer layer 124 is then formed over the substrate 110 as illustrated in FIG. 27. The accommodating buffer layer will form as a monocrystalline layer over the properly prepared (i.e., having the appropriate template layer) bare silicon surface in portion 1022. The portion of layer 124 that forms over portions 1024 and 1026, however, may be polycrystalline or amorphous because it is formed over a material that is not monocrystalline, and therefore, does not nucleate monocrystalline growth. The accommodating buffer layer 124 typically is a monocrystalline metal oxide (e.g. monocrystalline perovskite oxide) or nitride layer and typically has a thickness in a range of approximately 2-100 nanometers. In one particular embodiment, the accommodating buffer layer is approximately 5-15 nm thick. During the formation of the accommodating buffer layer, an amorphous intermediate layer 122 is formed along the uppermost silicon surfaces of the integrated circuit 103. This amorphous intermediate layer 122 typically includes an oxide of silicon and has a thickness and range of approximately 1-5 nm. In one particular embodiment, the thickness is approximately 2 nm. Following the formation of the accommodating buffer layer 124 and the amorphous intermediate layer 122, a template layer 125 is then formed and has a thickness in a range of approximately one to ten monolayers of a material. In one particular embodiment, the material includes titanium-arsenic, strontium-oxygen-arsenic, or other similar materials as previously described with respect to FIGS. 1-5.

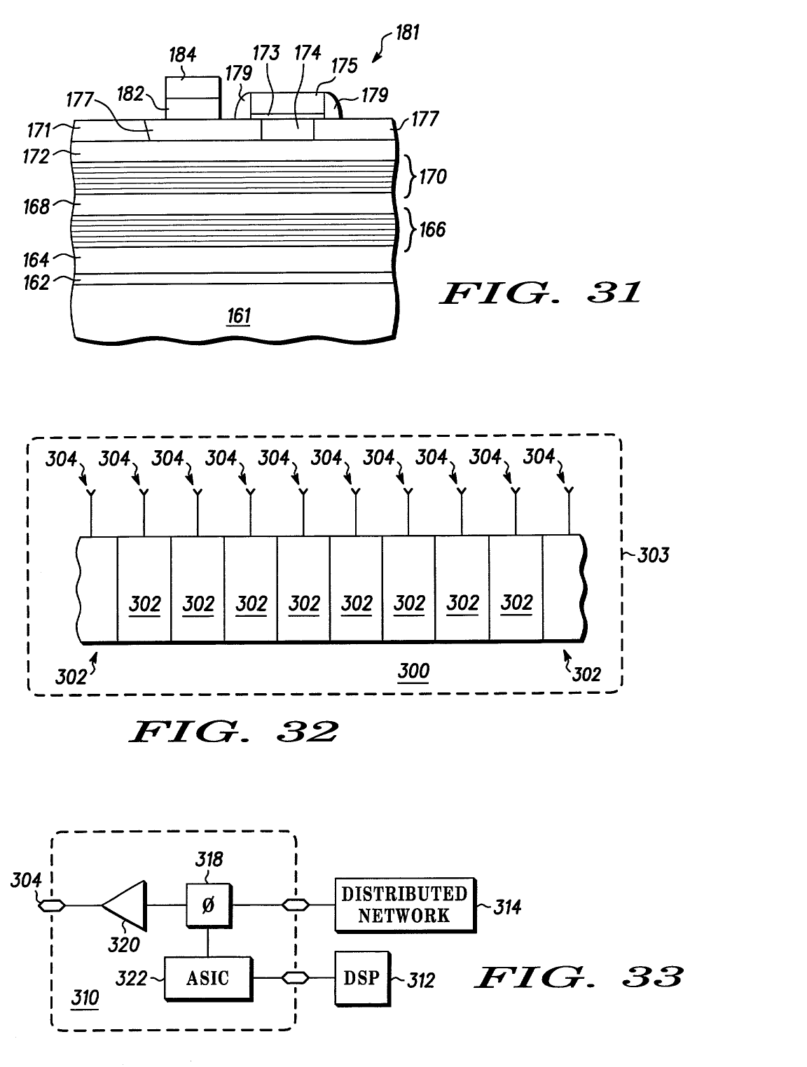

A monocrystalline compound semiconductor layer 132 is then epitaxially grown overlying the monocrystalline portion of accommodating buffer layer 124 as shown in FIG. 28. The portion of layer 132 that is grown over portions of layer 124 that are not monocrystalline may be polycrystalline or amorphous. The compound semiconductor layer can be formed by a number of methods and typically includes a material such as gallium arsenide, aluminum gallium arsenide, indium phosphide, or other compound semiconductor materials as previously mentioned. The thickness of the layer is in a range of approximately 1-5,000 nm, and more preferably 100-2000 nm. Furthermore, additional monocrystalline layers may be formed above layer 132, as discussed in more detail below in connection with FIGS. 31-32.

In this particular embodiment, each of the elements within the template layer are also present in the accommodating buffer layer 124, the monocrystalline compound semiconductor material 132, or both. Therefore, the delineation between the template layer 125 and its two immediately adjacent layers disappears during processing. Therefore, when a transmission electron microscopy (TEM) photograph is taken, an interface between the accommodating buffer layer 124 and the monocrystalline compound semiconductor layer 132 is seen.

After at least a portion of layer 132 is formed in region 1022, layers 122 and 124 may be subject to an annealing process as described above in connection with FIG. 3 to form a single amorphous accommodating layer. If only a portion of layer 132 is formed prior to the anneal process, the remaining portion may be deposited onto structure 103 prior to further processing.

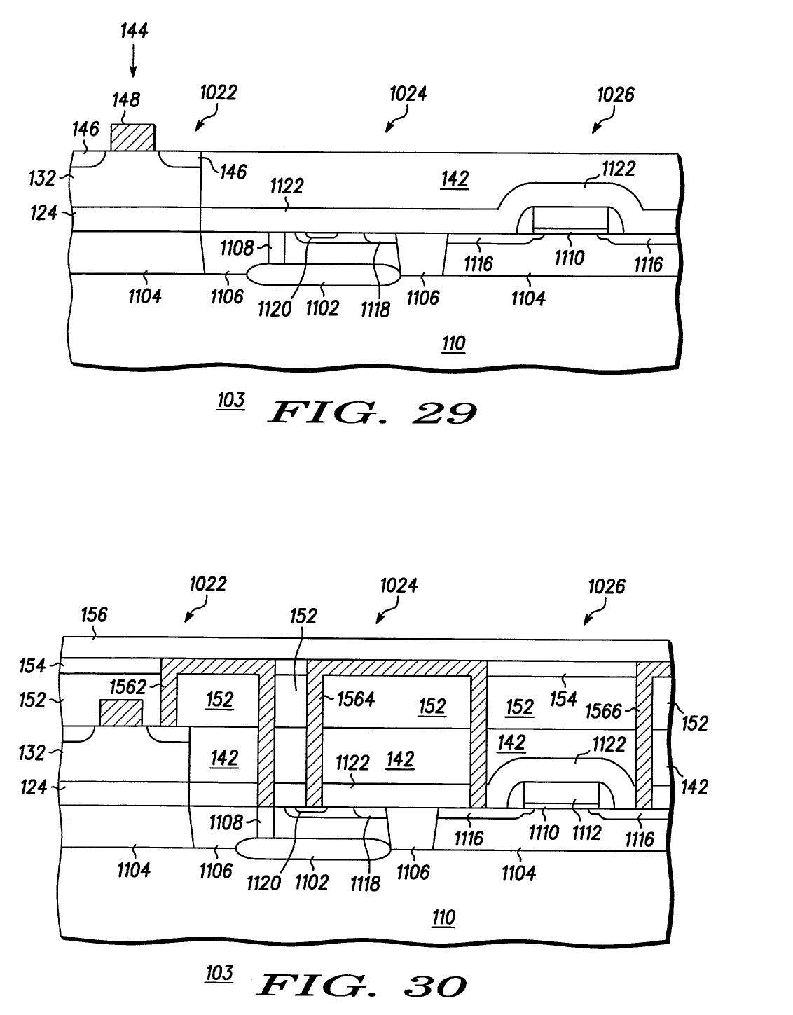

At this point in time, sections of the compound semiconductor layer 132 and the accommodating buffer layer 124 (or of the amorphous accommodating layer if the annealing process described above has been carried out) are removed from portions overlying the bipolar portion 1024 and the MOS portion 1026 as shown in FIG. 29. After the section of the compound semiconductor layer and the accommodating buffer layer 124 are removed, an insulating layer 142 is formed over protective layer 1122. The insulating layer 142 can include a number of materials such as oxides, nitrides, oxynitrides, low-k dielectrics, or the like. As used herein, low-k is a material having a dielectric constant no higher than approximately 3.5. After the insulating layer 142 has been deposited, it is then polished or etched to remove portions of the insulating layer 142 that overlie monocrystalline compound semiconductor layer 132.

A transistor 144 is then formed within the monocrystalline compound semiconductor portion 1022. A gate electrode 148 is then formed on the monocrystalline compound semiconductor layer 132. Doped regions 146 are then formed within the monocrystalline compound semiconductor layer 132. In this embodiment, the transistor 144 is a metal-semiconductor field-effect transistor (MESFET). If the MESFET is an n-type MESFET, the doped regions 146 and at least a portion of monocrystalline compound semiconductor layer 132 are also n-type doped. If a p-type MESFET were to be formed, then the doped regions 146 and at least a portion of monocrystalline compound semiconductor layer 132 would have just the opposite doping type. The heavier doped (N⁺) regions 146 allow ohmic contacts to be made to the monocrystalline compound semiconductor layer 132. At this point in time, the active devices within the integrated circuit have been formed. Although not illustrated in the drawing figures, additional processing steps such as formation of well regions, threshold adjusting implants, channel punchthrough prevention implants, field punchthrough prevention implants, and the like may be performed in accordance with the present invention. This particular embodiment includes an n-type MESFET, a vertical NPN bipolar transistor, and a planar n-channel MOS transistor. Many other types of transistors, including P-channel MOS transistors, p-type vertical bipolar transistors, p-type MESFETs, and combinations of vertical and planar transistors, can be used. Also, other electrical components, such as resistors, capacitors, diodes, and the like, may be formed in one or more of the portions 1022, 1024, and 1026.

Processing continues to form a substantially completed integrated circuit 103 as illustrated in FIG. 30. An insulating layer 152 is formed over the substrate 110. The insulating layer 152 may include an etch-stop or polish-stop region that is not illustrated in FIG. 30. A second insulating layer 154 is then formed over the first insulating layer 152. Portions of layers 154, 152, 142, 124, and 1122 are removed to define contact openings where the devices are to be interconnected. Interconnect trenches are formed within insulating layer 154 to provide the lateral connections between the contacts. As illustrated in FIG. 30, interconnect 1562 connects a source or drain region of the n-type MESFET within portion 1022 to the deep collector region 1108 of the NPN transistor within the bipolar portion 1024. The emitter region 1120 of the NPN transistor is connected to one of the doped regions 1116 of the n-channel MOS transistor within the MOS portion 1026. The other doped region 1116 is electrically connected to other portions of the integrated circuit that are not shown. Similar electrical connections are also formed to couple regions 1118 and 1112 to other regions of the integrated circuit.

A passivation layer 156 is formed over the interconnects 1562, 1564, and 1566 and insulating layer 154. Other electrical connections are made to the transistors as illustrated as well as to other electrical or electronic components within the integrated circuit 103 but are not illustrated in the FIGS. Further, additional insulating layers and interconnects may be formed as necessary to form the proper interconnections between the various components within the integrated circuit 103.

As can be seen from the previous embodiment, active devices for both compound semiconductor and Group IV semiconductor materials can be integrated into a single integrated circuit. Because there is some difficulty in incorporating both bipolar transistors and MOS transistors within a same integrated circuit, it may be possible to move some of the components within bipolar portion 1024 into the compound semiconductor portion 1022 or the MOS portion 1026. Therefore, the requirement of special fabricating steps solely used for making a bipolar transistor can be eliminated. Therefore, there would only be a compound semiconductor portion and a MOS portion to the integrated circuit. Passive semiconductor components can also be formed.

Monocrystalline semiconductor material layer configurations having three or more different layers of semiconductor material discussed above or other configurations may be used for forming semiconductor devices. FIG. 31 includes an illustration of a cross-section view of a portion of an integrated circuit 160 with more than two layers of semiconductor material. The integrated circuit 160 includes a monocrystalline silicon wafer 161. As discussed above, none, one or more semiconductor devices can be formed in or on the monocrystalline silicon wafer 161. An amorphous intermediate layer 162 and an accommodating buffer layer 164, similar to those previously described, have been formed over wafer 161. Layers 162 and 164 may be subject to an annealing process as described above in connection with FIG. 3 to form a single amorphous accommodating layer. In this specific embodiment, the monocrystalline compound semiconductor layers are formed over the accommodating buffer layer 164, followed by layers for a MOS transistor.

In FIG. 31, the lower layer 166 includes compound semiconductor materials. For example, the lower layer 166 comprises gallium arsenide or aluminum gallium arsenide. Optional layer 168 comprises an intermediate layer, accommodating buffer layer or additional monocrystalline compound semiconductor layer between the lower and upper layers 166 and 170. Upper layer 170 is formed in a similar manner to the lower layer 166 and includes compound semiconductor materials, such as indium phosphide. In one particular embodiment, the upper layer 170 may be p-type doped compound semiconductor materials, and the lower layer 166 may be n-type doped compound semiconductor materials. In alternate embodiments, one, two or more different layers of compound semiconductor materials with alternating layers of compound semiconductor materials are formed. Using known techniques, such as discussed herein, semiconductor devices are formed in the any of the monocrystalline compound semiconductor layers.

Another accommodating buffer layer 172, similar to the accommodating buffer layer 164, is formed over the upper layer 170. In an alternative embodiment, the accommodating buffer layers 164 and 172 may include different materials. However, their function is essentially the same in that each is used for making a transition between a compound semiconductor layer and a monocrystalline Group IV semiconductor layer. Layer 172 may be subject to an annealing process as described above in connection with FIG. 3 to form an amorphous accommodating layer. A monocrystalline Group IV semiconductor layer 174 is formed over the accommodating buffer layer 172. In one particular embodiment, the monocrystalline Group IV semiconductor layer 174 includes germanium, silicon germanium, silicon germanium carbide, or the like.

FIG. 31 further illustrates formation of another type of MOS transistor 181. A MOS portion is processed to form electrical components within the upper monocrystalline Group IV semiconductor layer 174. A field isolation region 171 is formed from a portion of layer 174. A gate dielectric layer 173 is formed over the layer 174, and a gate electrode 175 is formed over the gate dielectric layer 173. Doped regions 177 are source, drain, or source/drain regions for the transistor 181, as shown. Sidewall spacers 179 are formed adjacent to the vertical sides of the gate electrode 175. Other components can be made within at least a part of layer 174 or other layers 161, 166, 168, and 170. These other components include other transistors (n-channel or p-channel), capacitors, transistors, diodes, and the like.

A monocrystalline Group IV semiconductor layer is epitaxially grown over one of the doped regions 177. An upper portion 184 is P+ doped, and a lower portion 182 remains substantially intrinsic (undoped). The layer can be formed using a selective epitaxial process. In one embodiment, an insulating layer (not shown) is formed over the transistor 181 and the field isolation region 171. The insulating layer is patterned to define an opening that exposes one of the doped regions 177. At least initially, the selective epitaxial layer is formed without dopants. The entire selective epitaxial layer may be intrinsic, or a p-type dopant can be added near the end of the formation of the selective epitaxial layer. If the selective epitaxial layer is intrinsic, as formed, a doping step may be formed by implantation or by furnace doping. Regardless how the P+ upper portion 184 is formed, the insulating layer is then removed to form the resulting structure shown in FIG. 31.

Combinations of the exemplary semiconductor devices described above, other semiconductor devices or passive devices form phased array components. By using different semiconductor materials in one monolithic device (that is, one die separated from a wafer that has been processed using the techniques described above), to form the devices of a phased array, a more integrated phased array is formed. For example, processor or application specific integrated circuit components formed in silicon provide phased array control, and low noise amplifier components formed in gallium arsenide provide less noise interference than amplifiers formed in silicon. Phase shifters, amplifiers and other phased array components may be formed in different ones or multiple semiconductor materials as a function of desired operating characteristics. Combining multiple phased array components using different materials with different performance characteristics in an integrated circuit implemented in a monolithic device provides improved cost of manufacture, less noise and more versatility. Since phased arrays comprise a plurality of cells or similar sets of circuitry, integration provides for smaller phased array devices or a larger number of cells. A plurality of integrated circuits, which is to say a plurality of integrated circuit functions, can be implemented within one monolithic device.

Phased array components include (1) single or multiple circuits, such as amplifiers, phase shifters, mixers, processors, switches, oscillators, application specific integrated circuits or other circuits, (2) single or multiple, active or passive devices used for a circuit, such as transistors, resistors, capacitors, inductors or other discrete devices, (3) groupings of circuits, such as a receive or transmit path including an amplifier and a phase shifter, (4) groupings of semiconductor devices, such as multiple transistors forming part of an amplifier or phase shifter circuit, and (5) combinations thereof used in a phased array. Any one or more of the phased array components are formed as discussed above in one or more of the Group IV material, compound semiconductor material, intermediate layer material or amorphous layer material. For example, active phased array semiconductor components are formed in one or more of the Group IV or compound semiconductor materials, and passive phased array components are formed in any of the various layers discussed herein.

FIG. 32 illustrates a phased array 300 of one embodiment. The phased array 300 comprises a plurality of phased array cells 302 and a respective plurality of antennae 304. Each phased array cell 302 is associated with one antenna 304 for transmission and/or reception of energy at any frequency, such as radio frequencies, microwave frequencies, ultrasound frequencies, infrared frequencies or others. While shown arranged one dimensionally, the phased array cells 302 or antenna 304 can be arranged in two or three dimensions. FIG. 32 illustrates ten phased array cells 302, but more or fewer phased array cells 302 can be provided. For example, hundreds or even thousands of phased array cells 302 are used.

Phased array cells 302 include transmit path phased array components, receive path phased array components, phased array control components or combinations thereof. Each phased array cell 302 includes the same or different circuitry than other phased array cells 302. In one embodiment, the same circuitry is provided or repeated for each phased array cell 302. In other embodiments, a portion of the circuitry is shared between one or more of the phased array cells 302. For example, processor or control components are shared by multiple phased array cells 302.

One or more phased array components of one or more of the phased array cells 302 are integrated on one or more of the multiple types of semiconductor materials of a monolithic device as discussed above. In one embodiment, each of the phased array cells 302, including the transmit or receive path, is integrated on a monolithic device 303 303. Distribution circuitry, such as summers for combining signals from or transmit signal generators for generating waveforms for multiple phased array cells 302, can also be integrated on the monolithic device 303, but may be provided as devices separate from the monolithic device 303.

The antennae 304 comprise elements for radiating or intercepting energy. For example, the antennae 304 comprise metallized traces, patches, piezoelectric material, charge coupled devices, light sensing diodes or micro-electromechanical systems (MEMS)(e.g. membranes). FIG. 32 illustrates one antenna 304 for each phased array cell 302, but multiple antennae 304 for one phased array cell 302 can be used. For example, different antennae 304 are provided for left and right polarized signal transmission or reception. The antennae 304 are integrated on the monolithic device 303. For example, a metalized trace or patch is deposited within or on an outer surface of the monolithic device 303. As another example, a MEMS device is formed on the monolithic device 303 by deposition and etching, such as using complementary metal-oxide semiconductor (CMOS) processing. In yet another example, a light sensitive diode is formed in Group IV or compound semiconductor material. In other alternative embodiments, the antennae 304 are separate from but electrically connect with the monolithic device 303 and associated phased array cells 302.

Signals transmitted from or received by each antenna 304 and associated phased array cell 302 are delayed relative to other signals intercepted by the other antennae 304. The delay is implemented by time delay and/or phase delays. For transmission, the relative delays focus radiated energy at one or more locations. Energy radiated from multiple antennae 304 constructively sum in amplitude at the focal regions as a function of the delays. For reception, the relative delays focus the received signals for processing. Energy received from a focal region takes different amounts of time to travel to different antennae 304, so applying delays focuses the signals for correct summation. Each of signals being summed represents a specific location. By adjusting the delays as a function of time, signals for different transmit and receive focal areas are provided. For example, delays are dynamically changed during a receive event to focus received signals along a line. By changing focal points, a one, two or three dimensional area is scanned by the phased array 300. Each phased array cell 302 provides relative delays and associated signal processing in one embodiment.

FIG. 33 illustrates a transmit path component 310 of a phased array cell 302 and illustrates additional phased array components 314 and 312. The transmit path component 310 connects with the antenna 304, a digital signal processor 312 and a distribution network 314. The transmit path component 310 comprises an integrated circuit on monolithic device 303 having multiple semiconductor materials. The digital signal processor 312 and distribution network 314 represent one or more devices separate from the monolithic device 303 including the transmit path component 310. In alternative embodiments, part or all of one or both of the digital signal processor 312 and the distribution network 314 are integrated with the transmit path 310 on the monolithic device 303.

The distribution network 314 comprises summers (i.e. adders), transistors, application specific integrated circuits, processing devices, memory devices or other circuits for generating transmit signals and/or summing and filtering received signals. Any known or later developed active or passive devices for phased array processing can be used for the distribution network 314.

The digital signal processor 312 controls operation of the transmit path component 310, such as by selecting a phase delay. The digital signal processor 312 comprises one or more transistors and memory devices now known or later developed. In alternative embodiments, a general processor or application specific integrated circuit provides control instructions to the transmit path 310.

The transmit path component 310 comprises a phase shifter 318, an amplifier 320 and an application specific integrated circuit (ASIC) 322. Fewer, different or additional phased array components can be included in the transmit path component 310. The transmit path component 310 receives signals for transmission from the distribution network 314 and applies a phase shift according to control signals from the digital signal processor 312 or ASIC 322. The phase shifted signals are amplified and transmitted from the antenna 304. Other transmit path processing may be provided by the transmit path component 310, such as adding further delays, signal mixing, signal up-converting or down-converting, filtering, digital-to-analog conversion or other processing.

The phase shifter 318 comprises a line coupler, a switch for connecting different lengths of transmission line, a co-planar transmission line, a ferroelectric material responsive to an applied control voltage and deposited on the monolithic device 303, or other devices for shifting the phase of signals in the desired frequency range. In one embodiment, a transistor or MEMS switch selects between different lengths of transmission lines deposited in the monolithic device 303. For example, a switch network for selecting phase shifts in 22.5 degree increments (4 bit switching) is formed in the compound or Group IV semiconductor materials. Other increments of phased shift or materials for forming the switches or transmission lines can be used. For low loss phase shifting with a phased array component formed in a Group IV semiconductor material, a ground plane shielding the phase shifter 318 is formed or deposited. One or more of these phased array components are formed in one or more of the Group IV semiconductor material, the compound semiconductor material, the amorphous material, the intermediate layer material or other materials.

The amplifier 320 increases the amplitude of the signal to be transmitted. In one embodiment, the amplifier 320 comprises a radio and/or microwave frequency (RF/MW) integrated circuit that is included on the monolithic device 303, such as a monolithic microwave integrated circuit (MMIC) for amplification. The amplifier 320 can be a Doherty, distributed, low noise, high power, trans-impedance, other power combining or other non-power combining amplifier. The amplifier 320 includes components, such as transistors, inductors, capacitors, resistors, switches, combiners, splitters and/or other semiconductor devices. Other amplifier components, like matching circuitry (e.g. one or more inductors, resistors and/or capacitors), connected with ground, in feed back loops, to the amplifier input, to the amplifier output or other configurations are also formed in semiconductor or other material.

The types of transistors used for the amplifier 320 are a function of the material in which each transistor is formed. The material is selected as a function of the desired characteristics, such as bandwidth or other performance characteristic. Bi-polar junction transistors (BJT), laterally diffused metal-oxide semiconductors (LDMOS), complementary metal-oxide semiconductors (CMOS), hetero-junction bi-polar transistors (HBT), BiCMOS transistors or other transistors can be formed in silicon or Group IV materials. Field effect transistors (FET), MESFET, high electron mobility transistor (HEMT), pseudomorphic high electron mobility transistor (PHEMT), HBT or other transistors can be formed in gallium arsenide or other compound semiconductor materials. For example, HBT, HEMT, FET or other transistors can be formed in indium phosphide. The values of inductors, resistors and capacitors can also be a function of the material in which the amplifier component is formed. Using a plurality of materials provides for a broader range of operation.

The application specific integrated circuit (ASIC) 322 comprises one or more of control transistors, memory devices (RAM or ROM), or other semiconductor devices now known or later developed for processing data. The control transistors and other ASIC components implement processing specific to an application, such as clocking data to apply selected phase shifts in response to control signals. The control transistors include any of the transistors discussed herein. In alternative embodiments, a microprocessor or a digital signal microprocessor is used instead of the ASIC 322.

Part of, or the entire ASIC 322 is integrated on the monolithic device 303. In one embodiment, the ASIC 370 is formed as a array of transistors at least partly or entirely in the Group IV semiconductor portion of the monolithic device 303. Other parts of the ASIC 370 can be formed in other layers, such as the compound Group III-V semiconductor layer, the intermediate layer (e.g. amorphous oxide material), the accommodating buffer layer (e.g. monocrystalline perovskite oxide material), and/or external to the single monolithic.

The phased array components of the transmit path component 310 are integrated in different semiconductor materials or other materials of the monolithic device 303. For example, one phased array component is formed in a Group IV semiconductor material, and another phased array component is formed in a compound semiconductor material on the monolithic device 303. Passive components can be formed in oxide or other materials discussed herein.

Any of the phased array components described herein are formed in any of the materials also discussed herein in various combinations. For example, one transistor is formed in a Group IV semiconductor material, and another transistor is formed in a compounded semiconductor material or a different type of Group IV semiconductor material. As another example, one or more parts of the amplifier 320 (e.g. a first transistor formed in compound semiconductor material) are integrated in different semiconductor materials than other parts of the amplifier 320 (e.g. a second transistor formed in a Group IV semiconductor material), providing a broader frequency response. Other phased array components are formed in the same or different semiconductor materials, such as forming a phase shifter 318, ASIC 322, DSP 312 or distribution network 314 component in a Group IV semiconductor material (e.g. silicon) with one part of the amplifier 320 or in a compound semiconductor material with the other part of the amplifier 320. As yet another example, the application specific integrated circuit 322 or part thereof (e.g., a control transistor) is integrated in a silicon layer and the phase shifter, amplifier or parts of the phase shifter and/or amplifier are integrated in a compound semiconductor material of the monolithic device 303. In one embodiment, the amplifier 320 or a part thereof (e.g. a transistor) is formed in a compound semiconductor material, the ASIC 322 or a part thereof (e.g. a transistor) is formed in a Group IV semiconductor material and the phase shifter 318 or parts thereof are formed in one or both of the Group IV or compound semiconductor materials.

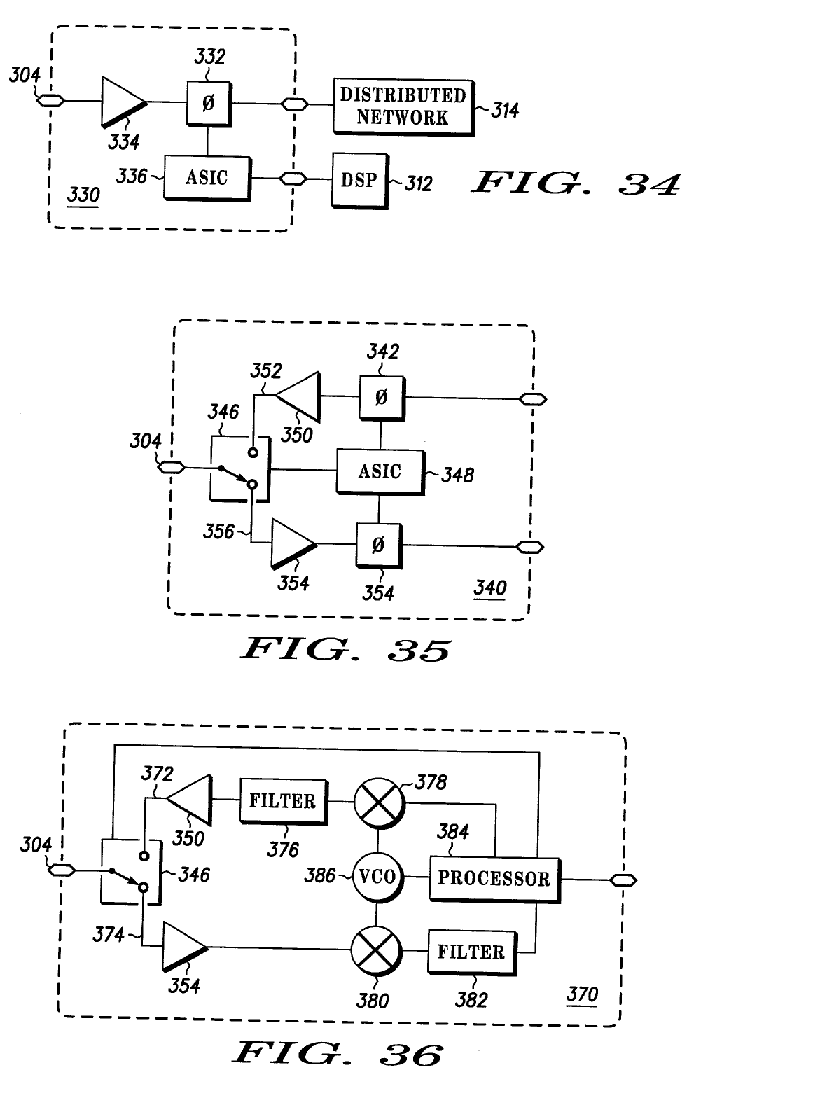

FIG. 34 illustrates a receive path component 330 of a phased array cell 302 (see FIG. 32) and illustrates additional phased array components 314 and 312. The receive path component 310 connects with the antenna 304, the digital signal processor 312 and the distribution network 314. The receive path component 330 comprises an integrated circuit on the monolithic device 303 having multiple semiconductor materials. The digital signal processor 312 and distribution network 314 represent one or more devices separate from the monolithic device 303 including the receive path component 330. In alternative embodiments, part or all of one or both of the digital signal processor 312 and the distribution network 314 are integrated on the monolithic device 303 with the receive path component 330.

The distribution network 314 and digital signal processor 312 are formed of the components discussed above for FIG. 33. In one embodiment, the same distribution network 314 and digital signal processor 312 are used for both the transmit path 310 and the receive path 330. In alternative embodiments, part or all of one or both of the distribution network 314 and digital signal processor 312 are separate or different components for the transmit path 310 and the receive path 330.

The receive path component 330 comprises a phase shifter 332, an amplifier 334 and an ASIC 336. The receive path component 330 receives signals from the antenna 304. The received signals are amplified and a phase shift is applied according to control signals from the digital signal processor 312 or the ASIC 336. Fewer, different or additional phased array components can be included in the receive path component 330. Other receive path processing may be provided by the receive path component 330, such as adding further delays, signal mixing, signal up-converting or down-converting, analog-to-digital conversion, filtering or other processing.

The phase shifter 332 and ASIC 336 comprises any of the components formed in any of the materials discussed above for the phase shifter 318 and ASIC 322, respectively (see FIG. 33). These components or parts of the components can be shared or used by both the transmit and receive path components 310, 330, but separate transmit and receive paths with separate phased array components can be used.

The amplifier 334 increases the amplitude of the received signal for further processing. The amplifier 334 can comprise any of the components of the amplifier 320 (see FIG. 33) formed any of the materials discussed herein. In one embodiment, the amplifier 334 comprises a low noise amplifier formed from transistors, resistors, inductors and/or capacitors in compound semiconductor materials. For example, one or more FETs are formed in indium phosphide. In this embodiment, a shorter gate length and/or shaped gate provides lower resistance for lower noise. The gate can be shaped as a large T or mushroom shape of metal deposited on a layer or surface of the integrated circuit. Other amplifier structures and components formed in any of the materials discussed herein can be used, such as CMOS transistors, LDMOS transistors or other transistors formed in a Group IV material, FET, MESFET, HEMT, PHEMT, HBT or other transistors formed in compound semiconductor materials.

The phased array components of the receive path component 330 are integrated in different semiconductor materials or other materials of the monolithic device 303. For example, one phased array component is formed in a Group IV semiconductor material, and another phased array component is formed in a compound semiconductor material on the monolithic device 303 or integrated circuit. Passive components can be formed in amorphous, intermediate, semiconductor or other materials discussed herein and integrated with active components formed in one or more semiconductor materials.

Any the phased array components described herein are formed in any of the materials also discussed herein in various combinations. Any of the combinations discussed above for the transmit path component 310 of FIG. 33 can be used in the receive path component 330. For example, one transistor is formed in a Group IV semiconductor material, and another transistor is formed in a compounded semiconductor material or a different type or layer of Group IV semiconductor material. In one embodiment, the amplifier 334 or a part thereof (e.g. a transistor) is formed in a compound semiconductor material, the ASIC 336 or a part thereof (e.g. a transistor) is formed in a Group IV semiconductor material and the phase shifter 332 or parts thereof are formed in one or both of the Group IV or compound semiconductor materials.

While each phased array cell 302 of FIG. 32 can comprise one of the transmit or receive path components 310, 330, one embodiment has both transmit and receive path components 310, 330 in the same phased array cell 302. FIG. 35 illustrates a transceiver component 340. The transceiver component 340 includes a transmit path 342 and a receive path 344 both connected with a switch 346. The switch 346 connects with the antenna 304. A common ASIC 348 controls the switch 346 and the transmit and receive paths 342 and 344. In alternative embodiments, separate ASICs are provided for each of the transmit and receive paths 342, 344. The ASIC 348 can be responsive to other circuitry on or external to the monolithic device 303.

The transceiver 340 comprises an integrated circuit on the monolithic device 303. One or more components of the transmit path 342 and the receive path 344 are formed on the monolithic device 303 as discussed above for the transmit path component 310 (see FIG. 33) and for the receive path component 330 (see FIG. 34). As shown in FIG. 35, the transmit path 342 includes an amplifier 350 and a phase shifter 352. The phase shifter 352 and amplifier 350 are formed as discussed above. The receive path 344 includes an amplifier 354 and a phase shifter 356. The phase shifter 352 and amplifier 350 are formed as discussed above. Additional or different transmit or receive path components can be used.

The switch 346 comprises any of the transistors discussed above (e.g. a FET switch). In alternative embodiments, the switch 346 comprises a micro-electromechanical system (MEMS)(e.g. a mechanical member formed in a semiconductor material that is moveable in response to electric signals), a PIN diode, or other device for selecting between the transmit path 342 and the receive path 344 in response to a control signal from the ASIC 348. The switch 346 is formed in one or more of the materials discussed herein, such as a Group IV or compound semiconductor material, an amorphous material or an intermediate material. In one embodiment, the switch 346 comprises a CMOS transistor formed in monocrystalline silicon.

To receive signals with the transceiver 340, the switch 346 is operated to pass signals from the antenna 304 to the receive path 344. To transmit signals with the transceiver 340, the switch 346 is operated to pass signals to the antenna 304 from the transmit path 342. The switch 346 isolates the transmit path 342 from the receive path 344.

The phased array components of the transceiver 340 are integrated in different semiconductor materials or other materials of the monolithic device 303. For example, one phased array component is formed in a Group IV semiconductor material, and another phased array component is formed in a compound semiconductor material on the monolithic device 303 or integrated circuit. Passive components can be formed in amorphous, intermediate, semiconductor or other materials discussed herein and integrated with active components formed in one or more semiconductor materials.

Any of the phased array components described herein are formed in any of the materials also discussed herein in various combinations. Any of the combinations discussed above for the transmit path component 310 of FIG. 33 and the receive path component 330 of FIG. 34 may be used for the transceiver 340. The switch 346 is integrated in the same or different materials than other phased array components. For example, the switch 346 is formed in a Group IV, such as silicon, semiconductor material with one or more transistors of the ASIC 348.

FIG. 36 illustrates an alternative transceiver 370 with alternative transmit and receive paths 372 and 374. The transmit path 372 includes the amplifier 350 discussed above, a filter 376 and a mixer 378. The receive path 374 includes the amplifier 354 discussed above, a mixer 380 and a filter 382. The transmit and receive paths 372, 374 are connected to the antenna 304 by the switch 346 discussed above. A processor 384 and voltage controlled oscillator 386 control the mixers 378 and 380. Different, additional or fewer phased array components are included in alternative embodiments.

The processor 384 comprises a digital signal processor, an ASIC, a general processor or other control device. For example, the processor 384 includes an array of transistors formed in one or more semiconductor materials. In one embodiment, a separate processor 384 is formed for each phased array cell 302. In alternative embodiments, the processor 384 or part of the processor 384 is shared by a plurality of phased array cells 302. The processor 384 is formed in part or entirely on the monolithic device 303. Alternatively, the processor 384 is formed on a separate monolithic device. The processor 384 controls the voltage controlled oscillator 386. The processor 384 can also generate transmit signals, process received signals and apply phase or delay shifts. Alternatively, other components, such as a distributed network, perform some or all of these functions.

The voltage controlled oscillator 386 comprises a network of transistors and resistors with a feedback connection or loop. Different frequencies are generated in response to an input voltage, such as a voltage from or controlled by the processor 384. Voltage controlled oscillators now known or later developed can be used. The voltage controlled oscillator 386 or components of the voltage controlled oscillator 386 are formed in any of the materials of the monolithic device 303. For example, active components, such as any of the transistors discussed above, are formed in one or more semiconductor (e.g. Group IV or compound) materials. Alternatively, the voltage controlled oscillator 386 is formed on a separate monolithic device.

The mixers 378 and 380 comprise one or more diodes arranged with multiple inputs for non-linear frequency conversion. Any non-linear (e.g. diodes, transistors, or semiconductor optical amplifier) or combination of non-linear devices (e.g. dual-gate FET mixer, or a ring or star configuration of diodes) with associated matching circuitry can be used. The diodes or other phased array components of the mixers 378 and 380 are formed in part or entirely in the monolithic device, such as in Group IV or compound semiconductor materials. The frequency response of the mixer 378, 380 is a function of the material used to form the parts of the mixer 378, 380. Compound semiconductor materials provide operation at high frequencies. For example, gallium arsenide components operate at higher frequencies than silicon or other Group IV materials. As another example, indium phosphide components operate at higher frequencies than gallium arsenide. The material or materials used for the mixer 378, 380 correspond to the desired operating frequencies.

In response to the frequency output by the voltage controlled oscillator 386, the mixer 378 up-converts or modulates the transmit signal to a higher frequency. The processor 384 provides an envelope or other signal at one frequency and the mixer 378 increases the frequency of the signal to be transmitted. For receiving signals, the mixer 380 down-converts or demodulates the received signal to a lower frequency. The processor 384 receives the down converted signal for further processing, such as phase-shifting, filtering, analog-to-digital conversion and summing with other signals.

The filters 376, 382 remove high frequency noise or other undesirable signals at the output of the mixers 378, 380. The filters 376, 382 comprise one or more resistors, capacitors, inductors and combinations thereof. Active components, such as transistors or diodes, can also be used. The filters 376, 382 are arranged as high pass, low pass or band pass filters using designs now know or later developed. All, part or none of the filters 376, 382 are formed in the monolithic device 303. For integrated resistors, nichrome, tantalum nitride or other lossy material forms the resistor. Alternatively, an epitaxial layer or other doped material formed on a semiconductor material, such as gallium arsenide, forms the resistor. For capacitors, a MEMS or other structure having two conductive plates (e.g. deposited metal layer or doped semiconductor material) separated by a gap is formed. For inductors, an air-bridge, planar spiral deposit or etch of metal, or a spiral of conductive material formed in one or multiple layers of material is formed.

Any of the phased array components described herein may be formed in any appropriate material also discussed herein, on the monolithic device 303. Any of the combinations discussed above for the transceiver 340 of FIG. 35 may be used for the transceiver 370. The mixers 378, 380, filters 376, 382, voltage controlled oscillator 386, and processor 384 are formed in one integrated circuit in one embodiment. For example, the processor 384 is formed in a Group IV material of the monolithic device 303. The voltage controlled oscillator 386 and mixers 378, 380 are formed in either or both of Group IV and compound semiconductor materials as a function of desired performance, such as frequency response. The filters 376, 382 are formed in semiconductor, intermediate, amorphous or other appropriate materials as a function of the desired inductor, capacitor and resistor values. Some of these components can be formed as or on separate devices.

By using different semiconductor materials in one monolithic device, a more integrated and versatile phased array is formed. For example, processor or application specific integrated circuit components formed in silicon provide phased array control, and low noise amplifier components formed in gallium arsenide generate less noise than amplifiers formed in silicon. Phase shifters, mixers, amplifiers and other phased array components may be formed in different ones or multiple semiconductor materials as a function of desired operating characteristics. Combining multiple phased array components with different performance characteristics in one monolithic device provides improved cost of manufacture. Since phased arrays comprises a plurality of cells or similar sets of circuitry, integration provides for smaller phased array devices or a larger number of cells.

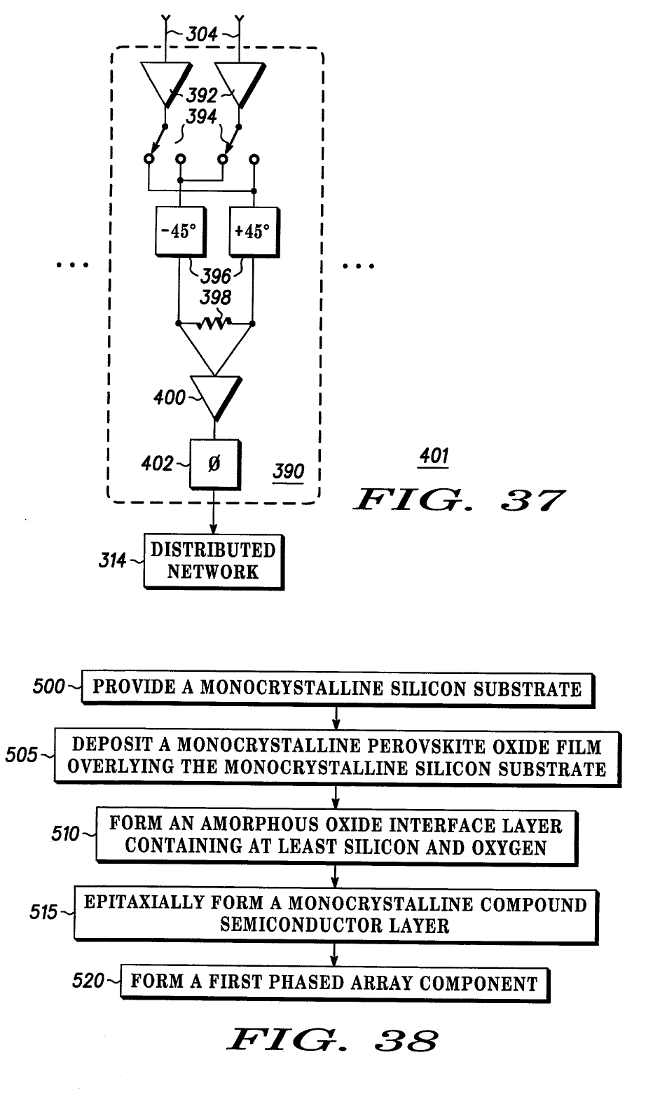

FIGS. 32-36 illustrate exemplary phased array circuits formed at least in part on one monolithic device 401 with multiple types of semiconductor materials. Other phased array circuits using the same, similar or different components can be used. FIG. 37 illustrates a phased array cell 390 of one such alternative embodiment. The phased array cell 390 comprises at least a receive path component connected with two antennae 304 and the distribution network 314. The two antennae 304 allow for reception of polarized signals, such as left and right circular polarized signals. The radio or other frequency output of the phased array cell 390 connects with the distributed network 314. The distributed network 314 also provides control signals and power to the phased array cell 390. The phased array components of the phased array cell 390 comprise the same or different types of components as discussed above for FIGS. 32-36.

The receive path component includes a pair of low noise amplifiers 392, a pair of switches 394, a pair of line couplers 396, a resistor 398, an amplifier 400 and a phase shifter 402 (e.g., a 4-bit phase shifter). An ASIC or processor can be provided as part of the phased array cell 390. The low noise amplifiers 392, switches 394 and line couplers 396 amplify, select an amplified signal and apply a phase shift for two received signals in two paths. These two phase shifts adjust for the polarization of the signal, such as one phase shift by +45 degrees and the other phase shift by −45 degrees. The two phase adjusted signals are combined and amplified by the amplifier 400. The phase shifter 402 adjusts the phase of the combined, amplified signal relative to other phased array cells.

Any of the phased array components of the phased array cell 390 are formed in one of multiple layers of materials. In one embodiment, the low noise amplifiers 392 are formed in a monocrystalline compound semiconductor material. The amplifier 400 and phase shifter 402 are formed as a function of frequency response in one or both of Group IV and compound semiconductor materials. The switches 394 and resistor 398 are formed in any of the materials of the monolithic device 401. The line couplers 396 are formed by depositing closely spaced metal traces or lines, such as forming a Lange coupler, branch line coupler, ring hybrid coupler or other coupler. The line couplers 396 can be formed on one or more of the semiconductor or other layers of material. Other combinations of components and/or materials can be used.

A plurality of phased array cells 390 connect with the distribution network 314. The plurality of phased array cells 390 are formed on the monolithic device 401, such in the same layers of compound and/or Group IV semiconductor materials. Since the monolithic device 401 includes different types of semiconductor material, a larger variety of components with different characteristics are integrated on one device. Integrating a plurality of such components for phased arrays allows for cost effective phased array integrated circuits.

In alternative embodiments, the phased array cell 390 is or additionally includes a transmit path. The same or similar components used for the receive path can be used for the transmit path. The amplifiers 392 and 400 pass the signal from the phase shifter 402 or line couplers 396, respectively, for transmission. For transmit, the amplifiers 392 can comprise power amplifiers.

FIG. 38 is a flow chart showing steps in the process used to fabricate the monolithic devices described with reference to FIGS. 1-37 above. At step 500, a monocrystalline silicon substrate is provided (meaning placed on a holder in equipment that can perform the next step). A monocrystalline perovskite oxide film is deposited at step 505, overlying the monocrystalline silicon substrate, the film having a thickness less than a thickness of the material that would result in strain-induced defects. At step 510, an amorphous oxide interface layer containing at least silicon and oxygen is formed at an interface between the monocrystalline perovskite oxide film and the monocrystalline silicon substrate. At step 515, a monocrystalline compound semiconductor layer is epitaxially formed overlying the monocrystalline perovskite oxide film. A first phased array component is formed at step 520 in one of the monocrystalline silicon substrate, the amorphous oxide material, the monocrystalline perovskite oxide material and the monocrystalline compound semiconductor material.

A composite integrated circuit, such as the phased array circuits and associated processors or ASICs, can have an electric connection for a power supply and a ground connection. The power and ground connections are in addition to the communications connections that are discussed above. Processing circuitry in a composite integrated circuit may include electrically isolated communications connections and include electrical connections for power and ground. Power supply and ground connections are usually well-protected by circuitry to prevent harmful external signals from reaching the composite integrated circuit. Ground connections may be isolated.

Further electrical isolation between semiconductor components can be provided. For example, the amplifier components are electrically isolated from the control processor components. Electrical isolation may be provided by etching a gap through one or more layers between semiconductor devices, and providing doped material in the etched gap. Channel walls or ground planes with different levels of doping may provide electrical isolation. Other electrical isolation techniques may be used.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential features or elements of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

I claim:

1. A monolithic device comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material; and
a first phased array component formed in at least one of the monocrystalline silicon substrate, the amorphous oxide material, the monocrystalline perovskite oxide material and the monocrystalline compound semiconductor material.

2. The structure of claim 1 wherein the first phased array component is formed in the monocrystalline silicon substrate.

3. The structure of claim 1 wherein the first phased array component is formed in the monocrystalline compound semiconductor material.

4. The structure of claim 3 wherein a second phased array component is formed in the monocrystalline silicon substrate.

5. The structure of claim 1 wherein the first phased array component comprises an application specific integrated circuit.

6. The structure of claim 1 wherein the first phased array component comprises a phase shifter.

7. The structure of claim 1 wherein the first phased array component comprises an amplifier.

8. The structure of claim 4 wherein the first phased array component comprises a first transistor and the second phased array component comprises a second transistor.

9. The structure of claim 4 wherein the first phased array component comprises a low noise amplifier and the second phased array component comprises an application specific integrated circuit.

10. The structure of claim 4 further comprising a mixer formed in one of the monocrystalline silicon substrate and the monocrystalline compound semiconductor material.

11. The structure of claim 4 further comprising a voltage controlled oscillator formed in one of the monocrystalline silicon substrate and the monocrystalline compound semiconductor material.

12. The structure of claim 4 further comprising a switch formed in the monocrystalline silicon substrate.

13. The structure of claim 4 wherein the first phased array component comprises a low noise amplifier and the second phased array component comprises a transistor;
further comprising a phase shifter component formed in one of the monocrystalline silicon substrate and the monocrystalline compound semiconductor material.

14. The structure of claim 4 wherein the second phased array component comprises control transistor and the first phased array component comprises one of a phase shifter and an amplifier transistor.

15. The structure of claim 1 wherein the first phased array component comprises a receive path operable to be connected with an antenna and a distribution network.

16. The structure of claim 1 wherein the first phased array component comprises a transmit path operable to be connected with an antenna and a distribution network.

17. The structure of claim 1 wherein the first phased array component comprises a transceiver having at least one switch operatively connectable with transmit and receive paths.

18. The structure of claim 1 wherein the first phased array component comprises one phased array cell operatively connected with an antenna and a distribution network and further comprising a plurality of additional phased array cells operatively connected with a respective plurality of additional antennae and the distribution network, the plurality of additional phased array cells formed in at least one of the monocrystalline silicon substrate and the monocrystalline compound semiconductor material.

19. A process for fabricating a monolithic device comprising:
(a) providing a monocrystalline silicon substrate;
(b) depositing a monocrystalline perovskite oxide film overlying the monocrystalline silicon substrate, the film having a thickness less than a thickness of the material that would result in strain-induced defects;
(c) forming an amorphous oxide interface layer containing at least silicon and oxygen at an interface between the monocrystalline perovskite oxide film and the monocrystalline silicon substrate;
(d) epitaxially forming a monocrystalline compound semiconductor layer overlying the monocrystalline perovskite oxide film; and
(e) forming a first phased array component in one of the monocrystalline silicon substrate, the amorphous oxide material, the monocrystalline perovskite oxide material and the monocrystalline compound semiconductor material.

20. The process of claim 19 wherein (e) comprises forming the first phased array component in the monocrystalline silicon substrate.

21. The process of claim 19 wherein (e) comprises forming the first phased array component in the monocrystalline compound semiconductor material.

22. The process of claim 21 further comprising:
(f) forming a second phased array component in the monocrystalline silicon substrate.

23. The process of claim 19 wherein (e) comprises forming an application specific integrated circuit.

24. The process of claim 19 wherein (e) comprises forming a phase shifter.

25. The process of claim 19 wherein (e) comprises forming an amplifier.

26. The process of claim 22 wherein (e) comprises forming a first transistor and (f) comprises forming a second transistor.

27. The process of claim 22 wherein (e) comprises forming a low noise amplifier and (f) comprises forming an application specific integrated circuit.

28. The process of claim 22 further comprising:
(g) forming a mixer in one of the monocrystalline silicon substrate and the monocrystalline compound semiconductor material.

29. The process of claim 22 further comprising:
(g) forming a voltage controlled oscillator in one of the monocrystalline silicon substrate and the monocrystalline compound semiconductor material.

30. The process of claim 22 further comprising:
(g) forming a switch in the monocrystalline silicon substrate.

31. The process of claim 22 wherein (e) comprises forming a low noise amplifier and (f) comprises forming a transistor;
further comprising:
(g) forming a phase shifter component in one of the monocrystalline silicon substrate and the monocrystalline compound semiconductor material.

32. The process of claim 22 wherein (f) comprises forming a control transistor and (e) comprises forming one of a phase shifter and an amplifier transistor.

33. The process of claim 19 wherein (e) comprises forming a receive path operable to be connected with an antenna and a distribution network.

34. The process of claim 19 wherein (e) comprises forming a transmit path operable to be connected with an antenna and a distribution network.

35. The process of claim 19 wherein (e) comprises forming a transceiver having at least one switch operatively connectable with transmit and receive paths.

36. The process of claim 19 wherein (e) comprises forming one phased array cell operatively connectable with an antenna and a distribution network; and
further comprising:
(f) forming a plurality of additional phased array cells operatively connectable with a respective plurality of additional antennae and the distribution network, the plurality of additional phased array cells formed in at least one of the monocrystalline silicon substrate and the monocrystalline compound semiconductor material.
